(19) United States
(12) Patent Application Publication
(10) Pub. No.: US 2026/0136742 A1
(43) Pub. Date: May 14, 2026

(54) DISPLAY PANEL AND MANUFACTURING METHOD THEREOF, AND DISPLAY DEVICE

(71) Applicant: Tianma Advanced Display Technology Institute (Xiamen) Co.,Ltd., Xiamen (CN)

(72) Inventors: Jingtao GUO, Xiamen (CN); Canyuan ZHANG, Xiamen (CN); Qiang GU, Xiamen (CN); Bo ZHOU, Xiamen (CN)

(21) Appl. No.: 19/059,334

(22) Filed: Feb. 21, 2025

(30) Foreign Application Priority Data
Nov. 14, 2024 (CN) 202411629111.9

(51) Int. Cl. H10H 29/80; H01L 25/16; H10H 29/01; H10H 29/37

(52) U.S. Cl. CPC H10H 29/8421; H10H 29/012; H10H 29/034; H10H 29/37; H10W 90/00

(57) ABSTRACT

The disclosure provides a display panel and a manufacturing method thereof, and a display device. The display panel and the display device include a substrate, a driving layer disposed on one side of the substrate, and a light emitting element and a blocking wall disposed on the side of the driving layer away from the substrate. The blocking wall is at least located between adjacent light emitting elements along a direction parallel to a plane where the substrate is located. The display panel also includes a first reflecting layer and a second reflecting layer, where the first reflecting layer is located on a side of an epitaxial layer of the light emitting element facing the driving layer, and the second reflecting layer is located on a sidewall of the blocking wall facing the light emitting element, and/or on a sidewall of the light emitting element.

### CROSS-REFERENCE TO RELATED DISCLOSURE

This application claims priority of Chinese Patent Application No. 202411629111.9 filed on Nov. 14, 2024, the entire content of which is hereby incorporated by reference.

### TECHNICAL FIELD

The application relates to the field of display technology, and in particular to a display panel and a manufacturing method thereof, and a display device.

### BACKGROUND

With the continuous development of science and technology, more and more display products, such as mobile phones, tablets, laptops and smart wearable devices, are widely used in people's daily life and work, bringing great convenience to people's daily life and work, and becoming an indispensable tool for people today.

For display products equipped with micro-light emitting devices (Micro LED), there is a common problem of low brightness due to the limitations of the small-size Micro LED structure itself.

### SUMMARY

In order to solve the above technical problems, the present disclosure provides a display panel and a manufacturing method thereof, and a display device, aiming to improve the overall brightness of the display products and enhance the display effect.

In one aspect, the present disclosure provides a display panel that includes a substrate; a driving layer disposed on one side of the substrate; a light emitting element and a blocking wall disposed on a side of the driving layer away from the substrate, where the blocking wall is at least located between adjacent light emitting elements in a direction parallel to a plane where the substrate is located; and a first reflective layer and a second reflective layer, where the first reflective layer is located on a side of an epitaxial layer of the light emitting element facing the driving layer, and the second reflective layer is located on a sidewall of the blocking wall facing the light emitting element, and/or the second reflective layer is located on a sidewall of the light emitting element.

In another aspect, the present disclosure provides a method for making a display panel, and the method includes providing a substrate, and forming a driving layer on one side of the substrate, where a side of the driving layer facing away from the substrate includes a connection pad; binding a light emitting element to a side of the driving layer facing away from the substrate, so that the light emitting element is electrically connected to the connection pad, and providing a first reflective layer on a side of an epitaxial layer of the light emitting element facing the driving layer; forming a blocking wall, where the blocking wall is located between adjacent light emitting elements; forming a flat layer at least between the blocking wall and the light emitting element; and forming a second reflective layer so that the second reflective layer is located on a sidewall of the blocking wall facing the light emitting element, and/or the second reflective layer is located on a sidewall of the light emitting element.

In another aspect, the present disclosure provides a display device including a display panel, where the display panel includes a substrate; a driving layer disposed on one side of the substrate; a light emitting element and a blocking wall disposed on a side of the driving layer away from the substrate, where the blocking wall is at least located between adjacent light emitting elements in a direction parallel to a plane where the substrate is located; and a first reflective layer and a second reflective layer, where the first reflective layer is located on a side of an epitaxial layer of the light emitting element facing the driving layer, and the second reflective layer is located on a sidewall of the blocking wall facing the light emitting element, and/or the second reflective layer is located on a sidewall of the light emitting element.

Other features of the present disclosure and advantages thereof will become apparent from the following detailed description of exemplary embodiments of the present disclosure with reference to the accompanying drawings.

### BRIEF DESCRIPTION OF THE DRAWINGS

The accompanying drawings, which are incorporated in and constitute a part of this specification, illustrate embodiments consistent with the present disclosure and, together with the description, serve to explain the principles of the present disclosure. In order to more clearly illustrate the embodiments of the present disclosure or the technical solutions in the existing technologies, the drawings essential for understanding the disclosed embodiments or the description of the existing technologies will be briefly introduced below. Obviously, for a person skilled in the art, other drawings may be obtained based on these drawings without paying any creative labor.

FIG. 1 is a plan view showing a structure of a display panel, in accordance with an embodiment of the present disclosure;

FIG. 2 is a cross-sectional view of the display panel in FIG. 1 taken along the line AA;

FIG. 3 is another AA cross-sectional view of the display panel in FIG. 1;

FIG. 4 is another AA cross-sectional view of the display panel in FIG. 1;

FIG. 5 is a schematic structural diagram of a light emitting element, in accordance with an embodiment of the present disclosure;

FIG. 6 is an enlarged schematic diagram of the first reflective layer in FIG. 2;

FIG. 7 is an enlarged schematic diagram of the second reflective layer in FIG. 2;

FIG. 8 is another enlarged schematic diagram of the first reflective layer in FIG. 2;

FIG. 9 is another enlarged schematic diagram of the second reflective layer in FIG. 2;

FIG. 10 is another AA cross-sectional view of the display panel in FIG. 1;

FIG. 11 is a diagram showing a relative position relationship between the first reflective layer and the second reflective layer in the spacing area;

FIG. 12 is another diagram showing the relative position relationship between the first reflective layer and the second reflective layer in the spacing area;

FIG. 13 is another diagram showing the relative position relationship between the first reflective layer and the second reflective layer in the spacing area;

FIG. 14 is another diagram showing the relative position relationship between the first reflective layer and the second reflective layer in the spacing area;

FIG. 15 is another diagram showing the relative position relationship between the first reflective layer and the second reflective layer in the spacing area;

FIG. 16 is a BB cross-sectional view of the display panel in FIG. 1;

FIG. 17 is another BB cross-sectional view of the display panel in FIG. 1;

FIG. 18 is another AA cross-sectional view of the display panel shown in FIG. 1;

FIG. 19 is a schematic diagram showing a partial arrangement of light emitting elements in a display panel;

FIG. 20 is a flowchart showing a process of making a display panel, in accordance with an embodiment of the present disclosure;

FIG. 21 is a schematic diagram showing a process of forming a driving layer in making a display panel;

FIG. 22 is a schematic diagram showing a process of making a display panel and binding a light emitting element;

FIG. 23 is a schematic diagram showing a process of forming a blocking wall in making a display panel;

FIG. 24 is a schematic diagram showing a process of forming a flat layer in making a display panel;

FIG. 25 is a schematic diagram showing a second reflective layer formed during the process of making a display panel;

FIG. 26 is a schematic diagram showing a process of forming an encapsulation layer in making a display panel;

FIG. 27 is a schematic diagram showing a process of making a display panel in which a second reflective layer and a third reflective layer are formed;

FIG. 28 is another schematic diagram showing the formation of the second reflective layer and the third reflective layer in the process of making the display panel; and

FIG. 29 is a schematic diagram showing a structure of a display device, in accordance with an embodiment of the present disclosure.

### DETAILED DESCRIPTION

In order to more clearly understand the objective, features and advantages of the present disclosure, the scheme of the present disclosure will be further described below. It should be noted that the embodiments of the present disclosure and the features in the embodiments may be combined with each other without conflict.

In the following description, many specific details are set forth to facilitate a full understanding of the present disclosure, but the present disclosure may also be implemented in other ways different from those described herein. It is obvious that the embodiments in the specification are only part of the embodiments of the present disclosure, rather than all of the embodiments.

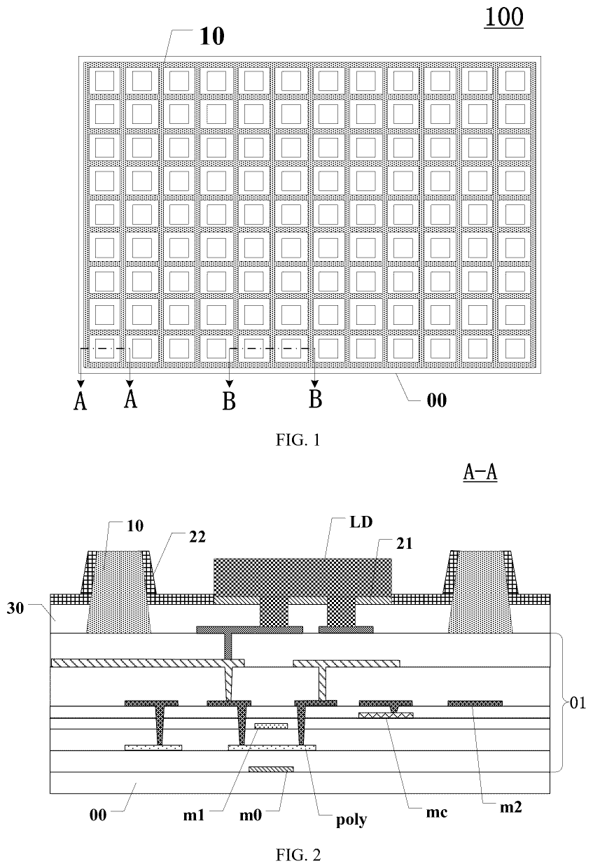

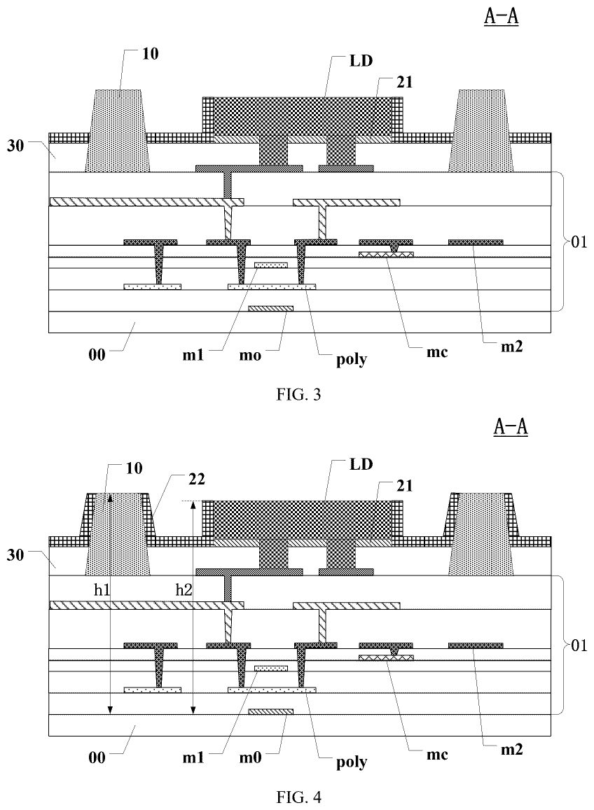

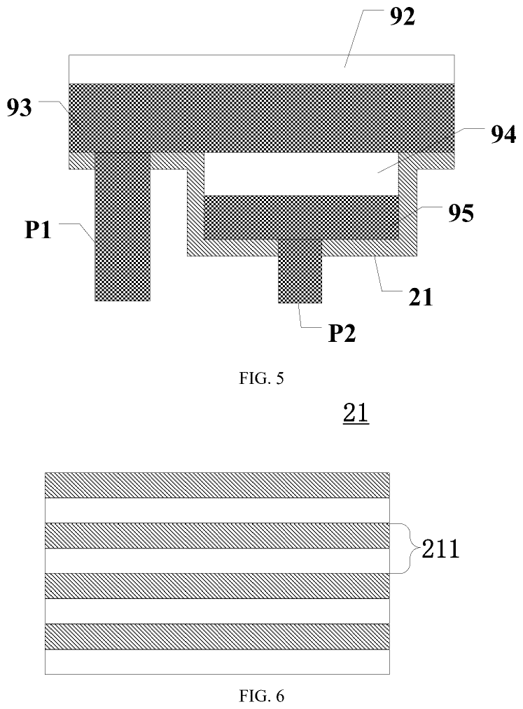

FIG. 1 is a planar structural diagram of a display panel, in accordance with an embodiment of the present disclosure, FIG. 2 is an AA-direction cross-sectional diagram of the display panel in FIG. 1, FIG. 3 is another AA-direction cross-sectional diagram of the display panel in FIG. 1, FIG. 4 is another AA-direction cross-sectional diagram of the display panel in FIG. 1, and FIG. 5 is a schematic structural diagram of a light emitting element, in accordance with an embodiment of the present disclosure. Referring to FIGS. 1-5, an embodiment of the present disclosure provides a display panel 100, including a substrate 00, a driving layer 01 disposed on one side of the substrate 00, and a light emitting element LD and a blocking wall 10 disposed on a side of the driving layer 01 away from the substrate 00. The blocking wall 10 is located at least between adjacent light emitting elements LD in a direction parallel to a plane where the substrate 00 is located. The display panel also includes a first reflective layer 21 and a second reflective layer 22. The first reflective layer 21 is located on a side of an epitaxial layer 92 of the light emitting element LD facing the driving layer 01. The second reflective layer 22 is located on a sidewall of the blocking wall 10 facing the light emitting element LD, and/or, the second reflective layer 22 is located on a sidewall of the light emitting element LD. That is, the first reflective layer 21 is located on the side of the epitaxial layer of the light emitting element LD facing the driving layer 01, and the second reflective layer 22 is located on the sidewall of the blocking wall 10 facing the light emitting element LD, and/or, the first reflective layer 21 is located on the side of the epitaxial layer of the light emitting element LD facing the driving layer 01, and the second reflective layer 22 is located on the sidewall of the light emitting element LD. The specific arrangement of the reflective layer will be described later.

It should be noted that FIG. 1 only illustrates a display panel with a rectangular structure as an example, and does not limit the actual shape of the display panel. In some embodiments, the display panel may also be embodied in any other feasible shape such as a circle, a rounded rectangle, etc. Optionally, the display panel in the disclosed embodiments may be a display panel using inorganic light emitting diode display technology, such as a Micro LED display panel, a Mini LED display panel, etc. This type of display panel has the advantages of high brightness, low power consumption, and easy splicing, and is widely used in display products. In the display panel shown in FIG. 1, the arrangement and number of the light emitting elements LD are only for illustration, and the present disclosure is not limited thereto. FIG. 2, FIG. 3 and FIG. 4 respectively illustrate a film layer structure of a display panel, the difference being that the position of the second reflective layer 22 is different, but the actual number and size of the film layers of the display panel are not limited thereto. In the film layer structure of the display panel, optionally, the gate of a transistor is set in a first metal layer m1, and the source and drain of the transistor are set in a second metal layer m2. The display panel also includes a semiconductor layer poly disposed on the side of the first metal layer m1 facing the substrate 00 and an auxiliary metal layer m0 disposed on the side of the semiconductor layer poly facing the substrate. It should be noted that the display panel may include a transistor with a dual-gate structure. At this point, one of the gates of the transistor may be located in the first metal layer m1, and the other gate may be located in the auxiliary metal layer m0. In a direction perpendicular to the plane where the substrate 00 is located, the first metal layer m1 and the auxiliary metal layer m0 overlap with the semiconductor layer poly. The auxiliary metal layer m0 also has a light-shielding function to prevent light from affecting the semiconductor layer poly. Optionally, a capacitor metal layer mc is further included between the first metal layer m1 and the second metal layer m2, and the capacitor metal layer mc may form a capacitor structure with the second metal layer m2. Optionally, a third metal layer m3 and a fourth metal layer m4 are also included on the side of the second metal layer m2 away from the substrate, and the third metal layer m3 and the fourth metal layer m4 may both be used to lay out signal lines.

FIG. 5 illustrates a structure of the light emitting element LD, and does not limit the specific shape and structure of the light emitting element LD. FIG. 5 takes the first reflective layer 21 as a part of the light emitting element LD as an example for explanation. That is, when the light emitting element LD is manufactured, the first reflective layer 21 is formed on one side of the epitaxial layer 92 of the light emitting element LD. At this time, the finished light emitting element LD itself includes the first reflective layer 21. When the display panel is manufactured, the light emitting element LD with the first reflective layer 21 is bound to the driving layer 01. However, the present disclosure is not limited to this. In some embodiments, the light emitting element LD and the first reflective layer 21 may also be two independent structures. That is, the finished product of the light emitting element LD does not include the first reflective layer 21, and the first reflective layer 21 may be formed on the side of the epitaxial layer 92 of the light emitting element LD facing the substrate 00 during the process of making the display panel. Optionally, the light emitting element LD includes an epitaxial layer 92, an n-type GaN contact layer 93, a quantum well light emitting layer 94 and a p-type GaN contact layer 95. The two electrodes P1 and P2 of the light emitting element LD are electrically connected to the n-type GaN contact layer 93 and the p-type GaN contact layer 95, respectively. It should be noted that the structure of the light emitting element LD in FIG. 5 is only for illustration, and does not limit the specific structure of the light emitting element LD actually included in the display panel. When the light emitting element LD is embodied as the structure shown in FIG. 5, the first reflective layer 21 is located on the surface of the n-type GaN contact layer 93 facing the electrode P1 and the surface of the p-type GaN contact layer 95 facing the electrode P2, and may also be located on the side of the p-type GaN contact layer 95 and the quantum well light emitting layer 94, so as to realize the reflection of at least part of the light emitted by the quantum well light emitting layer 94.

The present disclosure provides a light emitting element LD and a blocking wall 10 on the side of the array layer 02 facing away from the substrate 00. The blocking wall 10 is located between adjacent light emitting elements LD. In particular, the present disclosure introduces a first reflective layer 21 and a second reflective layer 22 into the display panel. The first reflective layer 21 and the second reflective layer 22 may be arranged in the following three ways.

In a first feasible arrangement, referring to FIG. 2, the first reflective layer 21 is located on the side of the epitaxial layer of the light emitting element LD facing the driving layer 01, and the second reflective layer 22 is located on the sidewall of the blocking wall 10 facing the light emitting element LD. When the light emitting element LD emits light, the first reflective layer 21 located on the side of the epitaxial layer of the light emitting element LD facing the substrate 00 will be able to reflect the light at the bottom of the light emitting element LD, so as to increase the amount of light emitted from the front view angle of the light emitting element LD, and to a certain extent improve the brightness of the light emitting element LD. When the light of a large viewing angle emitted by the light emitting element LD is emitted to the second reflective layer 22 on the sidewall of the blocking wall 10, it may be emitted to the light emitting surface of the display panel after being reflected by the second reflective layer 22. This is equivalent to effectively utilizing the light that may not be emitted from the light emitting surface of the display panel, thereby improving the effective utilization rate of the light emitted by the corresponding light emitting element LD. This then improves the luminous brightness of the corresponding light emitting element LD, and is conducive to increasing the amount of light emitted from the light emitting surface of the display panel, and improving the overall display brightness of the display panel. In the disclosed embodiment, the first reflective layer 21 and the second reflective layer 22 are respectively introduced into the bottom surface of the light emitting element LD and the sidewall of the blocking wall 10 located on the side of the light emitting element LD. The first reflective layer 21 and the second reflective layer 22 may be used to perform all-round reflection on the bottom light and the side light of the light emitting element LD, thereby effectively improving the reflection efficiency of the bottom light and the side light of the light emitting element LD.

In a second feasible arrangement, referring to FIG. 3, the first reflective layer 21 is located on the side of the epitaxial layer of the light emitting element LD facing the driving layer 01, and the second reflective layer 22 is located on the sidewall of the light emitting element LD. When the light emitting element LD emits light, the first reflective layer 21 located on the side of the epitaxial layer of the light emitting element LD facing the substrate 00 will be able to reflect the light at the bottom of the light emitting element LD, so as to increase the amount of light emitted from the front view of the light emitting element LD, and to a certain extent improve the brightness of the light emitting element LD. When the second reflective layer 22 is disposed on the sidewall of the light emitting element LD, the lateral light emitted by the light emitting element LD will be emitted to the second reflective layer 22. After the reflection of the second reflective layer 22, at least part of the light may be emitted to the light emitting surface of the display panel, which also increases the effective utilization rate of the light emitted by the light emitting element LD, which essentially improves the light emitting brightness of the corresponding light emitting element LD. This is conducive to increasing the amount of light emitted from the light emitting element LD to the light emitting surface of the display panel, and thus is also conducive to improving the overall display brightness of the display panel. In the disclosed embodiment, the first reflective layer 21 and the second reflective layer 22 fully wrap the bottom and side surfaces of the light emitting element LD. The reflective structure composed of the fully wrapped first reflective layer 21 and the second reflective layer 22 may effectively improve the reflection efficiency of the light emitting element LD in the side light and bottom light. In addition, the first reflective layer 21 and the second reflective layer 22 are directly in contact with the side surface of the light emitting element LD, thereby avoiding the transmission loss of the light from the light emitting element LD to the first reflective layer 21 or the second reflective layer 22.

In a third feasible arrangement, referring to FIG. 4, the first reflective layer 21 is located on the side of the epitaxial layer of the light emitting element LD facing the driving layer 01, and the second reflective layer 22 is located on the sidewall of the blocking wall 10 facing the light emitting element LD and the sidewall of the light emitting element LD. When the light emitting element LD emits light, the first reflective layer 21 located on the side of the epitaxial layer of the light emitting element LD facing the substrate 00 will be able to reflect the light at the bottom of the light emitting element LD, so as to increase the amount of light emitted from the front view of the light emitting element LD, and to a certain extent improve the brightness of the light emitting element LD. Of the light emitted from the side of the light emitting element LD, part of the light may be reflected by the second reflective layer 22 on the sidewall of the light emitting element LD, and part of the light may be reflected by the second reflective layer 22 on the sidewall of the blocking wall 10. The double reflection effect of the second reflective layer 22 located on the sidewall of the light emitting element LD and the second reflective layer 22 located on the sidewall of the blocking wall 10 is more conducive to increasing the amount of light reflected by the second reflective layer 22 to the light emitting surface of the display panel, effectively improving the light utilization rate and brightness of the corresponding light emitting element LD, thereby helping to improve the overall display brightness of the display panel. In the disclosed embodiment, the first reflection layer 21 located at the bottom of the light emitting element LD and the second reflection layer 22 located on the sidewall of the light emitting element LD are used to fully wrap the bottom surface and the side surface of the light emitting element LD. At the same time, the second reflection layer 22 is introduced into the sidewall of the blocking wall 10 located on the side of the light emitting element LD. By using the reflection structure composed of the first reflection layer 21 and the second reflection layer 22 that fully wrap the light emitting element LD, the transmission loss of the light of the light emitting element LD to the first reflection layer 21 or the second reflection layer 22 is avoided, so as to improve the reflection efficiency of the light emitting element LD in the side light and bottom light. The second reflection layer 22 located on the sidewall of the blocking wall 10 is further used to supplement the reflection of at least part of the light with a large viewing angle, which is conducive to further improving the overall reflection efficiency.

Continue to refer to FIG. 2, in some embodiments, the second reflective layer 22 is located on the sidewall of the blocking wall 10 facing the light emitting element LD, and the thickness of the first reflective layer 21 is less than the thickness of the second reflective layer 22.

Optionally, the first reflective layer 21 is a reflective layer provided by the light emitting element LD, and is formed on one side of the epitaxial layer of the light emitting element LD when the light emitting element LD is manufactured, so that most of the light emitted by the light emitting element LD that is directed toward the first reflective layer 21 may be reflected to the light emitting surface of the display panel through the first reflective layer 21, thereby improving the effective utilization rate of the light emitted by the light emitting element LD. The reflectivity of a reflective layer is related to its thickness. Within a certain thickness range, the greater the thickness, the higher the reflectivity. Since the second reflective layer 22 is formed after the light emitting element LD is bound to the display panel, when the second reflective layer 22 is formed on the sidewall of the blocking wall 10, the thickness of the second reflective layer 22 may be set to be greater than the thickness of the first reflective layer 21 in the light emitting element LD, thereby improving the reflectivity of the second reflective layer 22, so as to further improve the effective utilization rate of the light emitted by the light emitting element LD. In addition, when the first reflective layer 21 is a reflective layer provided by the light emitting element LD, when the bottom side light of the light emitting element LD is directed toward the first reflective layer 21, the transmission path is small, the light has no loss or has a small loss, which is conducive to improving the reflection efficiency of the light. Moreover, since the first reflective layer 21 is located at the bottom side of the light emitting element, the relative angle between the first reflective layer 21 and the light emitting element LD is fixed, so the reflection requirement for the first reflective layer 21 is relatively low. Considering that the second reflective layer 22 is at a certain distance from the light emitting element LD and the relative angle is not fixed, the reflection efficiency requirement for the second reflective layer 22 is relatively high. Therefore, in the disclosed embodiment, the thickness of the second reflective layer 22 is set to be greater than the thickness of the first reflective layer 21, which is beneficial to reducing additional preparation processes at the position of the first reflective layer 21 to save costs, and is beneficial to ensuring the reflectivity of the second reflective layer 22.

Optionally, the thickness of the first reflective layer 21 is 1 um≤H1≤1.5 um, the thickness of the second reflective layer 22 is 2 um≤H2≤3 um, and the reflectivity of the second reflective layer 22 is greater than or equal to 90%. When the first reflective layer 21 is part of the light emitting element LD, for the light emitting element LD, if the thickness of the first reflective layer 21 is too large, for example, greater than 1.5 um, the overall thickness of the light emitting element LD will be increased, which is not conducive to the miniaturization design of the light emitting element LD. If the thickness of the first reflective layer 21 is set too small, for example, less than 1 um, the first reflective layer 21 has a poor reflection effect on light. Therefore, the embodiments of the present disclosure set the thickness of the first reflective layer 21 to 1˜1.5 um, which may meet the miniaturization requirements of the light emitting element LD and the reflection requirements of the light emitted by the light emitting element LD, so that more light directed to the first reflective layer 21 may be directed to the light emitting surface of the display panel. Optionally, H1 may be 1.2 um, 1.4 um, etc., which is not specifically limited in the present disclosure.

In addition, considering that the second reflective layer 22 is made after the light emitting element LD is bound, the thickness of the second reflective layer 22 may be set to be greater than the thickness of the first reflective layer 21, so that the thickness is greater than or equal to 2 um, thereby effectively improving the reflectivity of the second reflective layer 22. Considering that the second reflective layer 22 is deposited on the sidewall of the blocking wall 10 facing the light emitting element LD, if it is too thick, for example, greater than 3 um, it will affect the adhesion between the second reflective layer 22 and the sidewall of the blocking wall 10, and increase the risk of separation of the second reflective layer 22 from the sidewall of the blocking wall 10. Therefore, the embodiments of the present disclosure set the thickness of the second reflective layer 22 to 2 um˜3 um, which may not only improve the reflectivity of the second reflective layer 22, but also help to improve the fixing reliability of the second reflective layer 22 and the sidewall of the blocking wall 10.

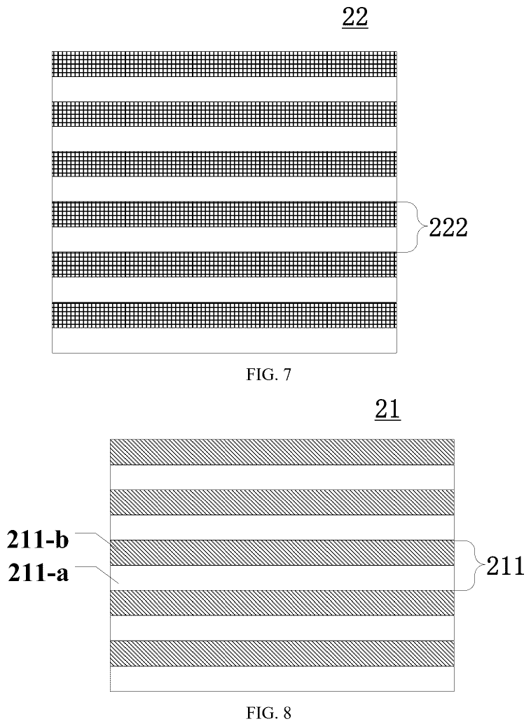

FIG. 6 is an enlarged schematic diagram of the first reflective layer 21 in FIG. 2, and FIG. 7 is an enlarged schematic diagram of the second reflective layer 22 in FIG. 2. Referring to FIG. 6 and FIG. 7, in some embodiments, the first reflective layer 21 includes M groups of first Bragg reflective layers 211, and the second reflective layer 22 includes N groups of second Bragg reflective layers 222, where 1≤M□N, and M and N are both integers. It should be noted that the number of Bragg reflective layers included in the first reflective layer 21 and the second reflective layer 22 shown in FIG. 6 and FIG. 7 is only for illustration, and does not limit the number of Bragg reflective layers actually included in the first reflective layer 21 and the second reflective layer 22. Optionally, 13≤N≤17.

In the disclosed embodiment, a first Bragg reflection layer 211 and a second Bragg reflection layer 222 are both embodied as a stacked structure of two sub-film layers, for example, a first Bragg reflection layer 211 and a second Bragg reflection layer 222 may be a stacked structure of a low refractive index material and a high refractive index material, for example, a stacked structure of silicon oxide and titanium oxide. A group of first Bragg reflection layers 211 includes a layer of silicon oxide and a layer of titanium oxide, and a group of second Bragg reflection layers 222 may also include a layer of silicon oxide and a layer of titanium oxide. Apparently, in some embodiments, the Bragg reflection layer may also be embodied as a stacked structure of other low refractive index materials and high refractive index materials. For example, the high refractive index material may also be titanium nitride or magnesium fluoride, forming a stacked structure of silicon oxide and titanium nitride or a stacked structure of silicon oxide and magnesium fluoride, which is not specifically limited in the present disclosure.

The disclosed embodiments show a solution in which the number of groups of the first Bragg reflection layers 211 included in the first reflection layer 21 is less than the number of groups of the second Bragg reflection layers 222 included in the second reflection layer 22. In this case, the thickness of the low refractive index material included in a group of the first Bragg reflection layers 211 may be set to be the same as the thickness of the low refractive index material included in a group of the second Bragg reflection layers 222, and the thickness of the high refractive index material included in a group of the first Bragg reflection layers 211 may be set to be the same as the thickness of the high refractive index material included in a group of the second Bragg reflection layers 222. In this way, the structure and thickness of the Bragg reflection layers in the first reflection layer 21 and the second reflection layer 22 are kept the same. By differentially setting the number of groups of the Bragg reflection layers included in the second reflection layer 22 and the first reflection layer 21, a differentiated design of the thickness of the second reflection layer 22 and the first reflection layer 21 may be achieved, so as to improve the reflectivity of the second reflection layer 22, and further improve the effective utilization rate of the light emitted by the light emitting element LD.

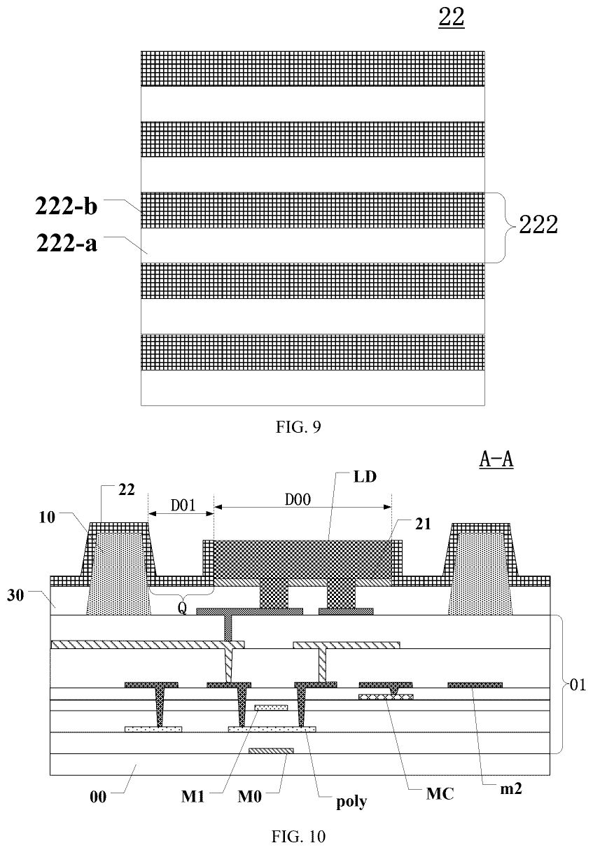

FIG. 8 is another enlarged schematic diagram of the first reflective layer 21 in FIG. 2, and FIG. 9 is an another enlarged schematic diagram of the second reflective layer 22 in FIG. 2. The difference between this embodiment and the embodiment shown in FIG. 6 and FIG. 7 is that the first reflective layer 21 and the second reflective layer 22 include the same number of Bragg reflective layers but having different thicknesses, and other similarities are not repeated here.

Referring to FIGS. 8 and 9, in some embodiments, the first reflective layer 21 includes M groups of first Bragg reflective layers 211, and the second reflective layer 22 includes N groups of second Bragg reflective layers 222, where 1≤M=N, and M and N are both integers. The thickness of the first Bragg reflective layer 211 is less than the thickness of the second Bragg reflective layer 222.

The thickness of the first Bragg reflection layer 211 mentioned in the present disclosure may be regarded as the total thickness of the high refractive index layer and the low refractive index layer in the first Bragg reflection layer 211, and the thickness of the second Bragg reflection layer 222 may be regarded as the total thickness of the high refractive index layer and the low refractive index layer in the second Bragg reflection layer 222. Alternatively, the thickness of the first Bragg reflection layer 211 may also be regarded as the sum of the thickness of the high refractive index layer and the low refractive index layer in a group of the first Bragg reflection layer 211, and the thickness of the second Bragg reflection layer 222 may be regarded as the sum of the thickness of the high refractive index layer and the low refractive index layer in a group of the second Bragg reflection layer 222. When the number of groups of Bragg reflection layers included in the first reflection layer 21 and the second reflection layer 22 is the same, the thickness of first Bragg reflection layer 211 and the second Bragg reflection layer 222 may be designed differently to achieve the differentiated design of the thickness of the first reflection layer 21 and the second reflection layer 22, so that the thickness of the second reflection layer 22 is greater than the thickness of the first reflection layer 21. This then improves the reflectivity of the second reflection layer 22, and further increases the amount of light reflected by the second reflection layer 22 to the light emitting surface of the display panel.

Continue to refer to FIG. 8 and FIG. 9, in some embodiments, the first reflective layer 21 includes M groups of first Bragg reflective layers 211, and the second reflective layer 22 includes N groups of second Bragg reflective layers 222, where M≥1, N≥1, and M and N are both integers. At least one first Bragg reflective layer 211 includes a first sub-reflective layer 211-a and a second sub-reflective layer 211-b, and the first sub-reflective layer 211-a and the second sub-reflective layer 211-b have different refractive indices, and/or the first sub-reflective layer 211-a and the second sub-reflective layer 211-b have different thicknesses. For any group of first Bragg reflective layers 211, the first sub-reflective layer 211-a and the second sub-reflective layer 211-b may have different refractive indices but the same thicknesses, or the first sub-reflective layer 211-a and the second sub-reflective layer 211-b may have different thicknesses but the same refractive indexes, or the first sub-reflective layer 211-a and the second sub-reflective layer 211-b may have different refractive indices and thicknesses. Thus, when light is incident on the first reflective layer 21, by setting the optical path of the light when it passes through the film layers with different refractive indexes and/or thicknesses in the Bragg reflective layer, it is possible to enhance the reflection, which is beneficial to improving the light emitting efficiency of the light emitting element. In addition, the first Bragg reflective layer 211 is an insulating film layer. In the disclosed embodiment, by setting the first reflective layer 21 to include at least one group of Bragg reflective layers, it is possible to avoid affecting the signal connection of the electrodes in the light emitting element (e.g., the signal connection between the two electrodes of the light emitting element), which is beneficial to ensuring the product reliability of the light emitting element.

Continue to refer to FIG. 8 and FIG. 9, in the second reflection layer 22 provided in the embodiment disclosed herein, at least one second Bragg reflection layer 222 includes a third sub-reflection layer 222-a and a fourth sub-reflection layer 222-b, and the third sub-reflection layer 222-a and the fourth sub-reflection layer 222-b have different refractive indices, and/or the third sub-reflection layer 222-a and the fourth sub-reflection layer 222-b have different thicknesses. For any group of second Bragg reflection layers 222, the third sub-reflection layer 222-a and the fourth sub-reflection layer 222-b may have different refractive indices but the same thicknesses, or the third sub-reflection layer 222-a and the fourth sub-reflection layer 222-b may have different thicknesses but the same refractive index, or the third sub-reflection layer 222-a and the fourth sub-reflection layer 222-b may have different refractive indices and thicknesses. Thus, when light is incident on the second reflective layer 22, by setting the optical path of the light when it passes through film layers with different refractive indices and/or thicknesses in the Bragg reflective layer, the reflection may be enhanced, which is beneficial to improving the light emitting efficiency of the light emitting element.

Referring to FIG. 4, in some embodiments, the distance between the surface of the blocking wall 10 facing away from the substrate 00 and the substrate 00 is h1, and the distance between the surface of the light emitting element LD facing away from the substrate 00 and the substrate 00 is h2, where h1≥h2. That is, on the side of the array layer 02 facing away from the substrate 00, the upper surface of the blocking wall 10 exceeds the upper surface of the light emitting element LD or is flush with the upper surface of the light emitting element LD. In this way, when the light emitting element LD emits light, the second reflective layer 22 located on the sidewall of the blocking wall 10 may receive a larger amount of light with a large viewing angle emitted by the light emitting element LD, and the amount of light reflected by the second reflective layer 22 to the light emitting surface of the display panel will be more, thereby being more conducive to improving the overall brightness of the display panel. In addition, setting the upper surface of the blocking wall 10 to be higher than the upper surface of the light emitting element LD is also conducive to blocking the large viewing angle light between light emitting elements LD of different colors, thereby being conducive to avoiding the problem of display color mixing.

FIG. 10 shows another AA cross-sectional view of the display panel in FIG. 1. The difference from the previous embodiments is that a second reflective layer 22 is also provided on the surface of the blocking wall 10 facing away from the substrate 00. Referring to FIG. 10, in some embodiments, the second reflective layer 22 is also located on the surface of the blocking wall 10 facing away from the substrate 00.

In the display panel, before the light emitted by the light emitting element LD is emitted to the light emitting surface of the display panel, some scattered light may exist between the light emitting element LD and the light emitting surface of the display panel, and this part of the light cannot be emitted from the light emitting surface of the display panel. When the second reflective layer 22 is introduced into the surface of the blocking wall 10 away from the substrate 00 (i.e., the upper surface of the blocking wall 10), when the scattered light is emitted to the second reflective layer 22, at least part of the light may be emitted to the light emitting surface of the display panel after being reflected by the second reflective layer 22, thereby facilitating the effective use of the light originally lost, and facilitating further improving the overall brightness of the display panel.

Continue to refer to FIG. 10, in some embodiments, the display panel also includes a flat layer 30. Along the direction parallel to the substrate 00, the flat layer 30 is located at least between the blocking wall 10 and the light emitting element LD. Along the direction perpendicular to the substrate 00, the flat layer 30 is located on the side of the first reflective layer 21 facing the substrate 00.

After the blocking wall 10 is formed on the side of the array layer 02 away from the substrate 00 and the light emitting element LD is bound, there may be gaps between the blocking wall 10 and the light emitting element LD, and between the two electrodes of the light emitting element LD. In this case, a flat layer 30 may be filled in these areas. Optionally, the flat layer 30 is a black light shielding layer. When the flat layer 30 is filled between the blocking wall 10 and the light emitting element LD, and between the two electrodes of the light emitting element LD, the metal in the array layer 02 may be shielded by the flat layer 30, and the electrodes of the light emitting element LD may also be shielded. This is helpful to avoid the problem of visible metal caused by the metal in the array layer 02 and the electrodes of the light emitting element LD, and is helpful to improve the display effect of the display panel. When the flat layer 30 is formed, the flat layer 30 covers the electrodes of the light emitting element LD, and the flat layer 30 is located on the side of the first reflective layer 21 facing the substrate 00, so as to avoid the flat layer 30 covering the first reflective layer 21 and affecting the light reflection function of the first reflective layer 21.

Continue to refer to FIG. 10, in some embodiments, there is a spacing area Q between the light emitting element LD and the blocking wall 10 adjacent to the light emitting element LD, and the second reflective layer 22 is also disposed in the spacing area Q and on the side of the flat layer 30 away from the substrate 00. The second reflective layer 22 located in the spacing area Q is connected to the second reflective layer 22 located on the sidewall of the light emitting element LD, and/or the second reflective layer 22 located in the spacing area Q is connected to the second reflective layer 22 located on the sidewall of the blocking wall 10.

When the second reflective layer 22 is introduced into the spacing area Q between the light emitting element LD and the blocking wall 10 adjacent to the light emitting element LD, the second reflective layer 22 may be formed simultaneously with the second reflective layer 22 on the sidewall of the blocking wall 10, and connected to the second reflective layer 22 on the sidewall of the blocking wall 10, so as to avoid the formation of a gap between the sidewall of the blocking wall 10 and the spacing area Q, which essentially increases the area of the second reflective layer 22 that may reflect light. This is beneficial to realize the reflection of light of different large view angles emitted by the light emitting element LD, and is beneficial to improving the utilization rate of light.

When the sidewall of the light emitting element LD is provided with a second reflective layer 22, the second reflective layer 22 in the spacing area Q may be formed simultaneously with the second reflective layer 22 on the sidewall of the light emitting element LD and the two may be connected to avoid the existence of a gap between the second reflective layer 22 on the sidewall of the light emitting element LD and the second reflective layer 22 in the spacing area Q, so as to avoid the light directed toward the gap from being unable to be utilized. In this way, the area between the spacing area Q and the sidewall of the light emitting element LD is thus covered by the second reflective layer 22, which is also beneficial to increase the coverage area of the second reflective layer 22, realize the reflection of light at different angles, and also help to improve the utilization rate of light.

When the sidewall of the light emitting element LD and the sidewall of the blocking wall 10 are both provided with the second reflective layer 22, the second reflective layer 22 in the spacing area Q may be respectively connected to the second reflective layer 22 on the sidewall of the light emitting element LD and the second reflective layer 22 on the sidewall of the blocking wall 10, so that the sidewall of the blocking wall 10, the sidewall of the light emitting element LD and the spacing area Q are all covered by the second reflective layer 22. This is more conducive to increasing the coverage area of the second reflective layer 22, so as to increase the reflection area of the second reflective layer 22, and increase the amount of light reflected by the second reflective layer 22 and emitted to the light emitting surface of the display panel, so as to further improve the light utilization rate of the light emitting element LD and improve the overall luminous brightness of the display panel.

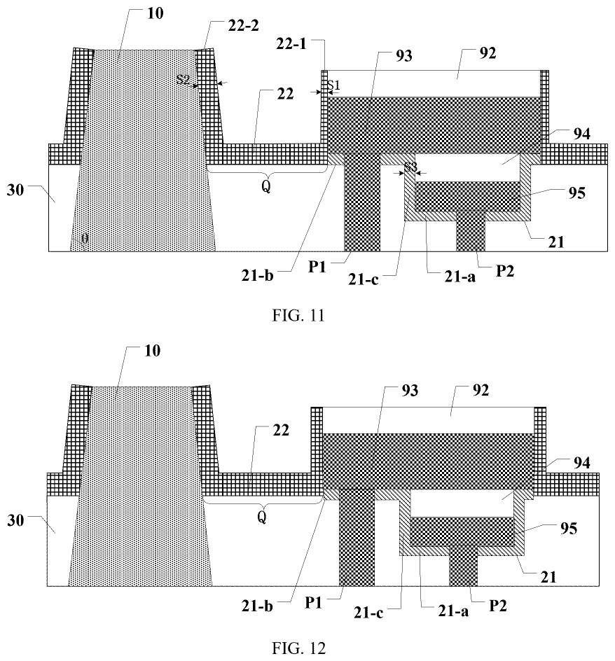

FIG. 11 is a diagram showing a relative position relationship between the first reflective layer 21 and the second reflective layer 22 in the spacing area Q. Referring to FIG. 11, in some embodiments, the first reflective layer 21 is in contact with the second reflective layer 22 in the spacing area Q. Referring to FIGS. 10 and 11, after the making of the blocking wall 10 and the binding of the light emitting element LD are completed on one side of the array layer 02, when the flat layer 30 is formed, the flat layer 30 does not completely cover the side surface of the first reflective layer 21, but exposes at least part of the side surface of the first reflective layer 21. In this way, when the second reflective layer 22 is formed on the side of the flat layer 30 away from the substrate 00, the second reflective layer 22 will be able to form contact with the first reflective layer 21 in the spacing area Q. The configuration of the second reflective layer 22 in contact with the first reflective layer 21 is conducive to improving the adhesion between the second reflective layer 22 and the first reflective layer 21, thereby improving the fixing reliability of the two. At the same time, it is conducive to improving the overall coverage area of the second reflective layer 22 and the first reflective layer 21, so as to help increase the amount of light that may be reflected by the first reflective layer 21 and the second reflective layer 22 as a whole, and further improve the overall display brightness of the display panel.

Continue to refer to FIGS. 10 and 11, in some embodiments, the first reflective layer 21 includes a first portion 21-a, a second portion 21-b and a connecting portion 21-c connecting the first portion 21-a and the second portion 21-b. The first portion 21-a and the second portion 21-b are respectively parallel to the plane where the substrate 00 is located, and the connecting portion 21-c is located between the first portion 21-a and the second portion 21-b in a direction perpendicular to the plane where the substrate 00 is located. The second portion 21-b is located on the side of the connecting portion 21-c away from the substrate 00, and the second portion 21-b is in contact with the second reflective layer 22 located in the spacing area Q on the side facing the spacing area Q.

In the disclosed embodiment, the non-planar structure of the side of the light emitting element LD facing the substrate 00 is used as an example for explanation. The first reflective layer 21 is adapted to the structure of the surface of the side of the light emitting element LD facing the substrate 00. The first reflective layer 21 includes a first portion 21-a, a connecting portion 21-c and a second portion 21-b connected in sequence. The first portion 21-a is located on the side of the connecting portion 21-c facing the substrate 00, and the second portion 21-b is located on the side of the connecting portion 21-c facing away from the substrate 00. The flat layer 30 covers the side of the connecting portion 21-c and at least exposes the side surface of the second portion 21-b. When the second reflective layer 22 is formed on the side of the flat layer 30 facing away from the substrate 00, the second reflective layer 22 will contact the second portion 21-b. The arrangement in which the second reflective layer 22 is in direct contact with the second portion 21-b in the first reflective layer 21 is conducive to improving the fixing reliability between the first reflective layer 21 and the second reflective layer 22, and is conducive to avoiding undesirable phenomena such as warping of the second reflective layer 22 in the spacing area Q.

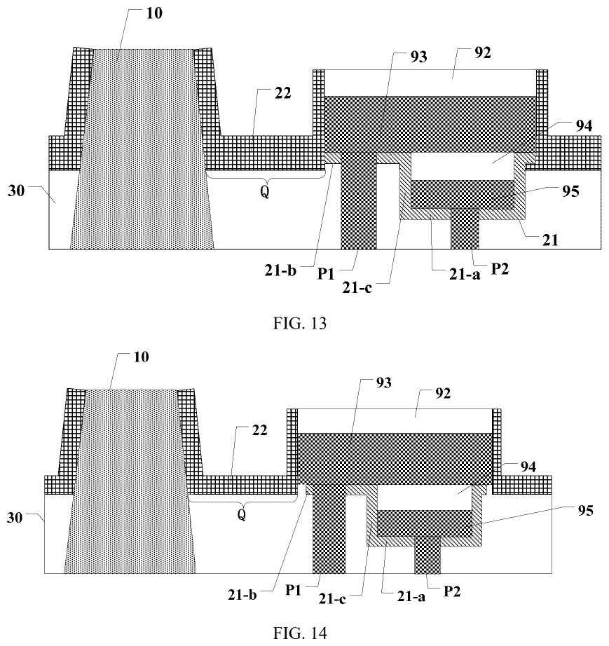

FIGS. 12 and 13 respectively show another relative position relationship diagram of the first reflective layer 21 and the second reflective layer 22 in the spacing area Q. FIGS. 11, 12 and 13 respectively show three relative position relationships between the second portion 21-b in the first reflective layer 21 and the second reflective layer 22 in the spacing area Q. In some embodiments, referring to FIG. 11 and optionally FIG. 10, the surface of the second portion 21-b facing the substrate 00 is flush with the surface of the second reflective layer 22 in the spacing area Q facing the substrate 00. In this way, the second portion 21-b in the first reflective layer 21 and the surface of the second reflective layer 22 facing the substrate 00 are located in the same plane, and the side of the second portion 21-b is completely exposed outside the flat layer 30. In this way, the entire side of the second portion 21-b is in contact with the second reflective layer 22 in the spacing area Q, which is beneficial to improving the fixing reliability between the second reflective layer 22 and the first reflective layer 21.

Alternatively, referring to FIG. 12 and optionally FIGS. 8-10, along the direction from the spacing area Q to the light emitting element LD, at least part of the sub-reflection layer in the second portion 21-b overlaps with the flat layer 30 in the spacing area Q, and at least part of the sub-reflection layer in the second portion 21-b does not overlap with the flat layer 30 in the spacing area Q, where the sub-reflection layer in the second portion 21-b that does not overlap with the flat layer 30 contacts the second reflective layer 22 in the spacing area Q. In the disclosed embodiment, at least part of the side surface of the second portion 21-b is covered by the flat layer 30, and at least part of the side surface is not covered by the flat layer 30. That is, the flat layer 30 only exposes at least part of the side surface of the second portion 21-b. When the second reflective layer 22 is formed in the spacing area Q, the second reflective layer 22 will be able to contact with the side surface of the second portion 21-b that is not covered by the flat layer 30, which may also improve the fixing reliability between the second reflective layer 22 and the first reflective layer 21 to a certain extent.

Alternatively, referring to FIG. 13 and optionally FIG. 10, along the direction perpendicular to the substrate 00, the second portion 21-b is located between two surfaces of the second reflective layer 22 in the spacing area Q that are parallel to the substrate 00. That is, along the direction from the spacing area Q to the light emitting element LD, the projection of the second portion 21-b is located within the projection range of the second reflective layer 22 in the spacing area Q, and this arrangement is conducive to increasing the contact area between the second reflective layer 22 and the first reflective layer 21, thereby facilitating the improvement of the fixing reliability between the second reflective layer 22 and the first reflective layer 21.

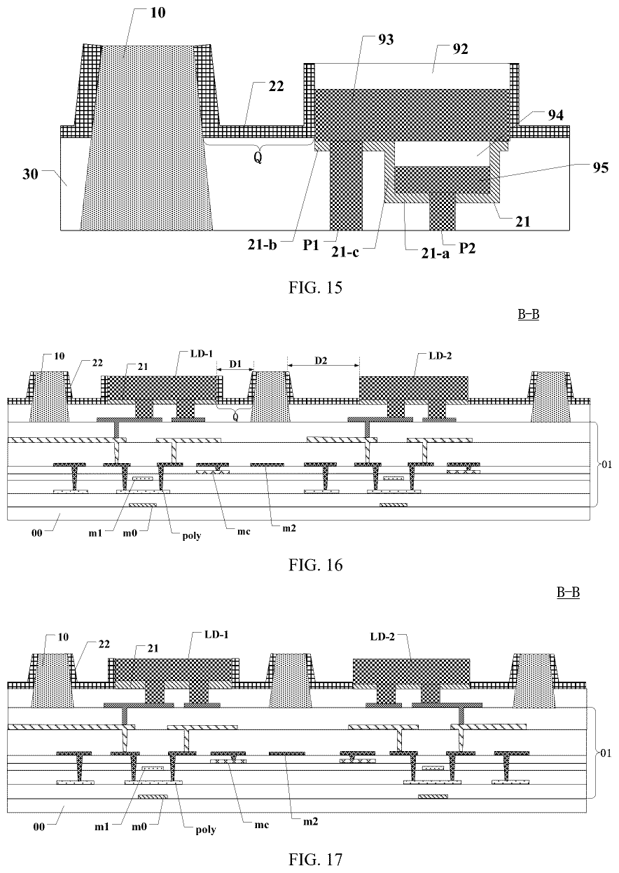

The above embodiments show a scheme in which the first reflective layer 21 is in contact with the second reflective layer 22 in the spacing area Q. In some embodiments, the first reflective layer 21 and the second reflective layer 22 in the spacing area Q may also be set to be non-contact according to needs. For example, referring to FIGS. 14 and 15, where FIGS. 14 and 15 respectively show another relative position relationship diagram of the first reflective layer 21 and the second reflective layer 22 in the spacing area Q. Referring to FIG. 14, along the direction of the blocking wall 10 pointing to the light emitting element LD, the first reflective layer 21 and the second reflective layer 22 located in the spacing area Q are isolated by the flat layer 30; and/or, referring to FIG. 15 and optionally FIG. 10, along the direction perpendicular to the plane where the substrate 00 is located, the first reflective layer 21 and the second reflective layer 22 located in the spacing area Q are isolated by the flat layer 30.

The illustrated embodiment in FIG. 14 shows a scheme in which the first reflective layer 21 and the second reflective layer 22 in the spacing area Q are isolated by the flat layer 30 in a direction parallel to the substrate 00, and the illustrated embodiment in FIG. 15 shows a scheme in which the first reflective layer 21 and the second reflective layer 22 in the spacing area Q are isolated by the flat layer 30 in a direction perpendicular to the substrate 00. Apparently, in some embodiments, the first reflective layer 21 and the second reflective layer 22 in the spacing area Q may be isolated by the flat layer 30 in both the horizontal direction (i.e., the direction parallel to the substrate 00) and the vertical direction (i.e., the direction perpendicular to the substrate 00). In the process of making the display panel, considering the thermal influence, the first reflective layer 21 and the second reflective layer 22 may expand due to heat, so the flat layer 30 is used to isolate the two, so as to reserve a certain space for the thermal deformation of the first reflective layer 21 and the second reflective layer 22.

Referring to FIG. 10, in some embodiments, there is a spacing area Q between the light emitting element LD and the blocking wall 10 adjacent to the light emitting element LD. The width D01 of the spacing area Q is smaller than the width D00 of the light emitting element LD along the direction of the blocking wall 10 pointing to the light emitting element LD. When the light emitting element LD emits light, at least part of the light at wide viewing angles may be further emitted to the light emitting surface of the display panel after being reflected by the second reflective layer 22 located on the sidewall of the blocking wall 10, thereby increasing the effective utilization rate of the light of the corresponding light emitting element LD. Since light will cause light loss during transmission, the longer the distance, the greater the light loss may be. If the width of the spacing area Q between the blocking wall 10 and the light emitting element LD is set too large, for example, greater than the width of the light emitting element LD, the light of the wide viewing angle emitted by the light emitting element LD will cause greater light loss during the transmission to the second reflective layer 22 on the sidewall of the blocking wall 10, which will affect the amount of light reflected from the second reflective layer 22 on the sidewall of the blocking wall 10 to the light emitting surface of the display panel. Therefore, when the width of the spacing region Q is set smaller than the width of the light emitting element LD in the disclosed embodiments, the light loss may be reduced to a certain extent, and the amount of light reflected to the light emitting surface of the display panel through the second reflective layer 22 may be increased, which is beneficial to improving the luminous brightness of the corresponding light emitting element LD.

FIG. 16 is a BB cross-sectional view of the display panel in FIG. 1. Referring to FIG. 16, in some embodiments, the display panel includes at least two light emitting elements LD-1 and LD-2 with different light emitting colors, and the widths of the spacing areas Q corresponding to the light emitting elements LD-1 and LD-2 with different light emitting colors are different.

When the light emitting colors of the light emitting elements LD are different, the light emitting efficiencies of the light emitting elements LD may be different. For the light emitting elements LD with different light emitting efficiencies, the widths of the corresponding spacing areas Q may be set differently. For example, assuming that the display panel includes a first-color light emitting element LD-1 and a second-color light emitting element LD-2, and the light emitting efficiency of the first-color light emitting element LD-1 is lower than that of the second-color light emitting element. In this case, the width D1 of the spacing area Q adjacent to the first-color light emitting element LD-1 may be set to be smaller than the width of the first-color light emitting element LD-1, and the width D2 of the spacing area Q adjacent to the second-color light emitting element LD-2 may be set to be smaller than the width of the second-color light emitting element LD-2. At the same time, the width D1 of the spacing area Q adjacent to the first-color light emitting element LD-1 may be set to be smaller than the width D2 of the spacing area Q adjacent to the second-color light emitting element LD-2. In this way, a large portion of the light emitted by the first color light emitting element LD-1 at a large viewing angle will be able to be directed toward the second reflective layer 22 on the sidewall of the blocking wall 10, and then be directed toward the light emitting surface of the display panel after being reflected by the second reflective layer 22. Thus, it is equivalent to increasing the actual luminous brightness of the first color light emitting element LD-1 by differentially designing the amount of light reflected by the second reflective layer 22, thereby reducing the difference in luminous brightness between the first color light emitting element LD-1 and the second color light emitting element LD-2 with different luminous efficiencies. This is beneficial to improving the uniformity of the overall display brightness of the display panel. Optionally, the first color light emitting element LD-1 is a red light emitting element LD, and the second color light emitting element LD-2 is a green light emitting element or a blue light emitting element.

Referring to FIG. 11, in some embodiments, the second reflective layer 22 includes a first section 22-1 located on the sidewall of the light emitting element LD and a second section 22-2 located on the sidewall of the blocking wall 10. The thickness of the first section 22-1 is S1, the thickness of the second section 22-2 is S2, and the thickness of the first reflective layer 21 is S3, where S1□S3□S2.

This embodiment shows a solution in which the sidewall of the light emitting element LD and the sidewall of the blocking wall 10 facing the light emitting element LD are provided with a second reflective layer 22, where the second reflective layer 22 located on the sidewall of the light emitting element LD is a first section 22-1, and the second reflective layer 22 located on the sidewall of the blocking wall 10 is a second section 22-2, where the thickness S1 of the first section 22-1 is less than the thickness S2 of the second section 22-2. Both the first section 22-1 and the second section 22-2 may include stacked Bragg reflective layers, and the number of groups of the Bragg reflective layers included in the first section 22-1 is less than that of the second section 22-2. When the second reflection layer 22 is actually manufactured, after the manufacture of part of the Bragg reflection layers on the sidewall of the light emitting element LD and the sidewall of the blocking wall 10 is completed, the Bragg reflection layers on the sidewall of the light emitting element LD constitute the first section 22-1. Subsequently, other Bragg reflection layers may be manufactured on the sidewall of the blocking wall 10, thereby forming the second section 22-2 on the sidewall of the blocking wall 10, but no Bragg reflection layers are manufactured again on the sidewall of the light emitting element LD. The thickness S1 of the first section 22-1 is made less than the thickness S3 of the first reflection layer 21, and less than the thickness S2 of the second section 22-2. Taking into account the limitation of the structure of the light emitting element LD itself, if a second reflective layer 22 with a relatively large thickness is formed on the sidewall thereof, the greater the thickness of the second reflective layer 22, the greater the risk of separation of the second reflective layer 22 from the sidewall of the light emitting element LD. Therefore, in the disclosed embodiment, when the thickness S1 of the second reflective layer 22 (i.e., the first section 22-1) located on the sidewall of the light emitting element LD is set to be smaller than the thickness S3 of the first reflective layer 21, it is beneficial to reduce the risk of separation of the first section 22-1 from the sidewall of the light emitting element LD.

In addition, considering that the present disclosure may improve the adhesion between the second reflecting layer 22 and the blocking wall 10 and reduce the risk of separation of the second reflecting layer 22 from the blocking wall 10 by adjusting the inclination of the sidewall of the blocking wall 10 and the coverage area of the second reflecting layer 22 on the blocking wall 10, the present disclosure sets the thickness S2 of the second section 22-2 located on the sidewall of the blocking wall 10 to be greater than the thickness S3 of the first reflecting layer 21. While avoiding the separation of the second reflecting layer 22 from the blocking wall 10, the reflectivity of the second reflecting layer 22 on the sidewall of the blocking wall 10 may also be improved by increasing the thickness of the second reflecting layer 22 on the sidewall of the blocking wall 10.

Optionally, continue to refer to FIG. 11, the angle between the sidewall of the blocking wall 10 and the bottom surface of the blocking wall 10 is 60°≤θ≤80°. If the angle between the sidewall of the blocking wall 10 and the bottom surface of the blocking wall 10 is set to be smaller, for example, less than 60°, if the upper surface of the blocking wall 10 is still kept higher than the upper surface of the light emitting element LD, the area occupied by the blocking wall 10 in the display panel will be larger, affecting the pixel density of the display panel. If the angle between the sidewall of the blocking wall 10 and the bottom surface of the blocking wall 10 is set to be larger, for example, greater than 80°, the slope of the sidewall of the blocking wall 10 will be steeper, affecting the adhesion of the second reflective layer 22 to the blocking wall 10, and increasing the risk of the second reflective layer 22 peeling off from the sidewall of the blocking wall 10. Therefore, in the embodiments of the present disclosure, the angle between the sidewall of the blocking wall 10 and the bottom surface of the blocking wall 10 is set to 60°˜80°, which may not only prevent the blocking wall 10 from occupying too much space of the display panel, which is beneficial to improving the pixel density of the display panel, but also improve the fixing reliability between the second reflective layer 22 and the sidewall of the blocking wall 10, thereby preventing the second reflective layer 22 from peeling off from the sidewall of the blocking wall 10.

In the present disclosure, another feasible implementation method for improving the fixing reliability between the second reflective layer 22 and the blocking wall 10 is that the sidewall of the blocking wall 10 and the surface of the blocking wall 10 facing away from the substrate 00 are covered with the second reflective layer 22. For example, referring to FIG. 10, the second reflective layer 22 located on the surface of the blocking wall 10 facing away from the substrate 00 is connected to the second reflective layer 22 located on the sidewall of the blocking wall 10. The second reflective layer 22 on the surface of the blocking wall 10 facing away from the substrate 00 may pull the second reflective layer 22 on the sidewall of the blocking wall 10, which is beneficial to reduce or avoid the problem of peeling off between the second reflective layer 22 and the sidewall of the blocking wall 10.

Referring to FIG. 16, in some embodiments, the display panel includes at least two light emitting elements LD of different luminous colors, and the thickness of the first reflective layer 21 corresponding to the light emitting elements LD of different luminous colors is the same. The first reflective layer 21 is disposed on the side of the epitaxial layer of the light emitting element LD facing the substrate 00, and is used to reflect the light directed to the bottom of the light emitting element LD to improve the light utilization rate of the light emitting element LD. When light emitting elements LD of different luminous colors are arranged in the display panel, the thickness of the first reflective layer 21 corresponding to the light emitting elements LD of different luminous colors may be set to be the same, which is conducive to achieving a uniform setting of the first reflective layer 21 and is conducive to reducing the difficulty of making the display panel.

Apparently, in some embodiments, the thickness of the first reflective layer 21 corresponding to at least some of the light emitting elements LD of different light emitting colors may also be differentiated. For example, referring to FIG. 17, which shows another BB cross-sectional view of the display panel in FIG. 1. In some embodiments, the light emitting element LD includes a first color light emitting element LD-1 and a second color light emitting element LD-2. The luminous efficiency of the first color light emitting element LD-1 is lower than the luminous efficiency of the second color light emitting element LD-2, and the thickness of the first reflective layer 21 corresponding to the first color light emitting element LD-1 is greater than the thickness of the first reflective layer 21 corresponding to the second color light emitting element LD-2.

When light emitting elements LD of different colors are arranged in the display panel, there is a difference in the luminous efficiency of at least some of the light emitting elements LD of different colors. The disclosed embodiment is explained by taking the luminous efficiency of the first color light emitting element LD-1 being lower than the luminous efficiency of the second color light emitting element LD-2 as an example. Under the same conditions, the luminous brightness of the light emitting element LD with low luminous efficiency will be lower than the luminous brightness of the light emitting element LD with high luminous efficiency. In the disclosed embodiment, the thickness of the first reflective layer 21 corresponding to the first color light emitting element LD-1 and the second color light emitting element LD-2 with different luminous efficiency is designed differently, so that the thickness of the first reflective layer 21 corresponding to the first color light emitting element LD-1 with lower luminous efficiency is greater than the thickness of the first reflective layer 21 corresponding to the second color light emitting element LD-2 with higher luminous efficiency, so as to increase the amount of light that may be reflected by the first reflective layer 21 corresponding to the first color light emitting element LD-1 with lower luminous efficiency. This thus increases the amount of light actually emitted by the first color light emitting element LD-1 to the light emitting surface of the display panel, and increases the brightness of the first color light emitting element LD-1, so as to balance the difference in luminous brightness between the first color light emitting element LD-1 and the second color light emitting element LD-2 with different luminous efficiency, thereby helping to improve the overall display brightness uniformity of the display panel.

Referring to FIGS. 17 and 6-9, in some embodiments, the first reflective layer 21 corresponding to the first color light emitting element LD-1 includes M1 group of first Bragg reflective layers 211, and the first reflective layer 21 corresponding to the second color light emitting element LD-2 includes M2 group of first Bragg reflective layers 211. As shown in FIGS. 6 and 7, M1>M2; or, as shown in FIGS. 8 and 9, M1=M2, and the thickness of the first Bragg reflective layer corresponding to the first color light emitting element LD-1 is greater than the thickness of the first Bragg reflective layer corresponding to the second color light emitting element LD-2.

In order to make the thickness of the first reflective layer 21 corresponding to the first color light emitting element LD-1 greater than the thickness of the first reflective layer 21 corresponding to the second color light emitting element LD-2, a feasible setting method is to increase the number of groups of Bragg reflective layers included in the first reflective layer 21 corresponding to the first color light emitting element LD-1, as shown in FIGS. 6 and 7. At the same time, the thickness of the Bragg reflective layers corresponding to the first color light emitting element LD-1 and the thickness of the Bragg reflective layers corresponding to the second color light emitting element LD-2 are set to be the same. This is equivalent to adding at least one more Bragg reflective layer on the first reflective light emitting element LD compared to the second color light emitting element LD-2. This setting method is conducive to simplifying the overall design difficulty of the first reflective layer 21 corresponding to different color light emitting elements LD.

In order to make the thickness of the first reflective layer 21 corresponding to the first color light emitting element LD-1 greater than the thickness of the first reflective layer 21 corresponding to the second color light emitting element LD-2, another feasible setting method is that, as shown in FIGS. 8 and 9, the number of groups of Bragg reflective layers included in the first reflective layer 21 corresponding to the first color light emitting element LD-1 and the number of groups of Bragg reflective layers included in the first reflective layer 21 corresponding to the second color light emitting element LD-2 are the same. The difference is that the thickness of the Bragg reflective layer corresponding to the first color light emitting element LD-1 is greater than the thickness of the Bragg reflective layer corresponding to the second color light emitting element LD-2. This method may also increase the thickness of the first reflective layer 21 corresponding to the first color light emitting element LD-1, thereby improving the light emitting brightness of the first color light emitting element LD-1.

In some embodiments, the first color light emitting element LD-1 is a red light emitting element, and the second color light emitting element LD-2 is a green light emitting element or a blue light emitting element. By increasing the thickness of the first reflective layer 21 corresponding to the red light emitting element LD, the light emitting brightness of the red light emitting element may be increased, the difference in light emitting brightness between the red light emitting element and the green light emitting element or the blue light emitting element may be reduced, and the overall display brightness uniformity of the display panel may be improved.

Optionally, the thickness of the first reflective layer 21 corresponding to the red light emitting element is 1.5 um, and the thickness of the first reflective layer 21 corresponding to the green light emitting element and the blue light emitting element is 1 um.

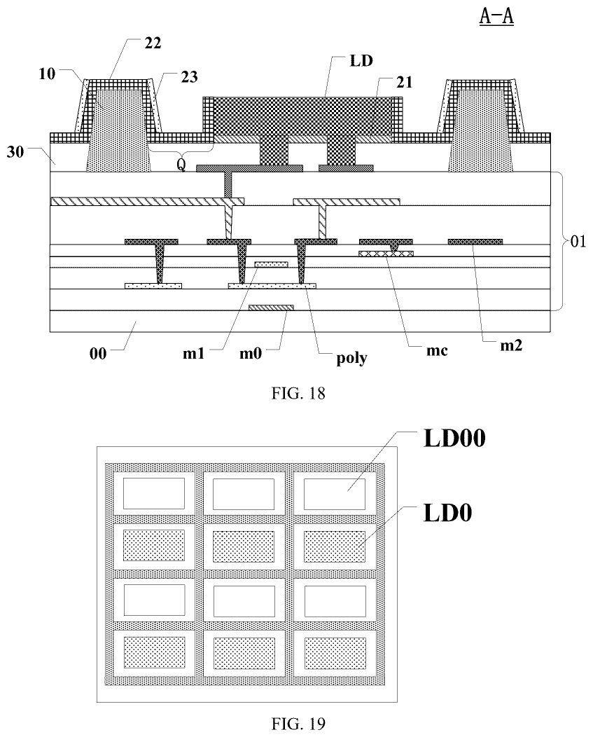

FIG. 18 is another AA cross-sectional view of the display panel shown in FIG. 1. Referring to FIG. 18, in some embodiments, the display panel also includes a third reflective layer 23. The third reflective layer 23 is at least disposed on the side of the second reflective layer 22 of the sidewall of the blocking wall 10 away from the sidewall of the blocking wall 10, and the reflectivity of the third reflective layer 23 is greater than the reflectivity of the second reflective layer 22.

Specifically, the embodiment disclosed herein shows a solution of introducing a third reflective layer 23 with a higher reflectivity into the display panel. The third reflective layer 23 is at least located on the surface of the second reflective layer 22 on the sidewall of the blocking wall 10 that is away from the blocking wall 10. By introducing the third reflective layer 23 with a higher reflectivity, it is beneficial to improve the reflection efficiency of the third reflective layer 23 for light, thereby increasing the amount of light reflected via the third reflective layer 23 to the light emitting surface of the display panel, so that more light emitted by the light emitting element LD that might not have been able to emit from the display panel may be effectively utilized, thereby being more beneficial to improving the light output of the light emitting element LD and improving the overall display brightness of the display panel.

The third reflective layer 23 is a reflective layer made of a metal material. In some embodiments, the third reflective layer 23 includes one of Au, Ag, and Al. When the third reflective layer 23 is formed of materials such as Au, Ag, or Al, the reflection efficiency of the third reflective layer 23 to light may be effectively improved, and the effective utilization rate of the light emitted by the light emitting element LD may be improved. When the third reflective layer 23 is a metal reflective layer, due to the limitation of the material itself, it is difficult for the metal reflective layer to be directly attached to the sidewall or surface of the structure such as the blocking wall 10. Considering that the metal reflective layer may be well attached to the surface of the Bragg reflective layer, in the embodiment disclosed herein, after the second reflective layer 22 is formed in the display panel, the third reflective layer 23 is formed on at least part of the surface of the second reflective layer 22, which is beneficial to improving the fixing reliability of the third reflective layer 23 in the display panel and improving the overall reflection efficiency of the reflective layer in the display panel.

Considering that if a metal reflective layer with a large area is formed on the display panel, there may be a risk of causing a short circuit, affecting the normal display function of the display panel, therefore, in some embodiments, the surface area of the third reflective layer 23 is smaller than the surface area of the second reflective layer 22. In other words, the third reflective layer 23 is not formed on the entire surface of the second reflective layer 22, and the third reflective layer 23 may be formed in a selected area of the display panel. For example, when the second reflective layer 22 is located on the upper surface of the blocking wall 10 (i.e., the surface facing away from the substrate 00), the sidewall of the blocking wall 10, the sidewall of the light emitting element LD, and the spacing area Q between the blocking wall 10 and the sidewall of the light emitting element LD, the third reflective layer 23 may be formed on the surface of the second reflective layer 22 on the sidewall of the blocking wall 10 and the surface of the second reflective layer 22 in the spacing area Q, so as to achieve effective reflection of the light of the light emitting element LD with a wide viewing angle. It may be selected whether to form the third reflective layer 23 on the surface of the second reflective layer 22 on the sidewall of the light emitting element LD according to actual needs, and it may be selected whether to form the third reflective layer 23 on the upper surface of the blocking wall 10 according to actual needs. In this way, the area where the third reflective layer 23 is provided may reflect the light by the third reflective layer 23, and the area where the third reflective layer 23 is not provided may reflect the light by the second reflective layer 22, so as to fully improve the overall reflection efficiency of the reflective layer in the display panel. Moreover, the third reflective layer 23 is not provided on the entire surface of a large area, so it is helpful to reduce the risk of short circuit caused by the large-area provision of metal of the third reflective layer 23.

FIG. 19 is a schematic diagram of a partial arrangement of the light emitting elements LD in the display panel. Referring to FIG. 19, in some embodiments, the light emitting elements LD includes a regular light emitting element LD00 and a redundant light emitting element LD0 arranged corresponding to the regular light emitting element LD00. FIG. 19 distinguishes the regular light emitting element LD00 from the redundant light emitting element LD0 by different fillings, but does not limit the specific structure. In the process of making the display panel, in addition to binding the regular light emitting element LD00 on the surface of the array layer away from the substrate 00, a binding area for the redundant light emitting element LD0 may be set on the array layer for binding the redundant light emitting element LD0. When the display panel is inspected, if it is found that some of the regular light emitting elements LD00 do not emit light, the corresponding redundant light emitting element LD0 may replace the regular light emitting element LD00 to emit light, thereby realizing the repair function of the display panel. The light emitting elements LD mentioned in the embodiments of the present disclosure may apply to a regular light emitting element LD00 and a redundant light emitting element LD0. That is, the relative position relationship and size relationship of the blocking wall 10, the first reflective layer 21, the second reflective layer 22 and other structures corresponding to the regular light emitting element LD00 and the redundant light emitting element LD0 may refer to the setting method of the above-mentioned embodiments. Even if the redundant light emitting element LD0 replaces the regular light emitting element LD00 to emit light, the second reflective layer 22 or the third reflective layer 23 may also be used to realize the reflection function of light, thereby improving the effective utilization rate of the light emitted by the corresponding light emitting element LD.

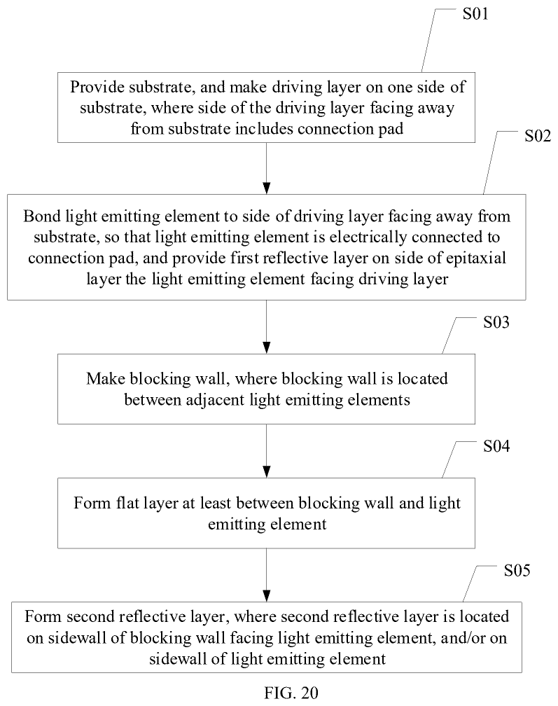

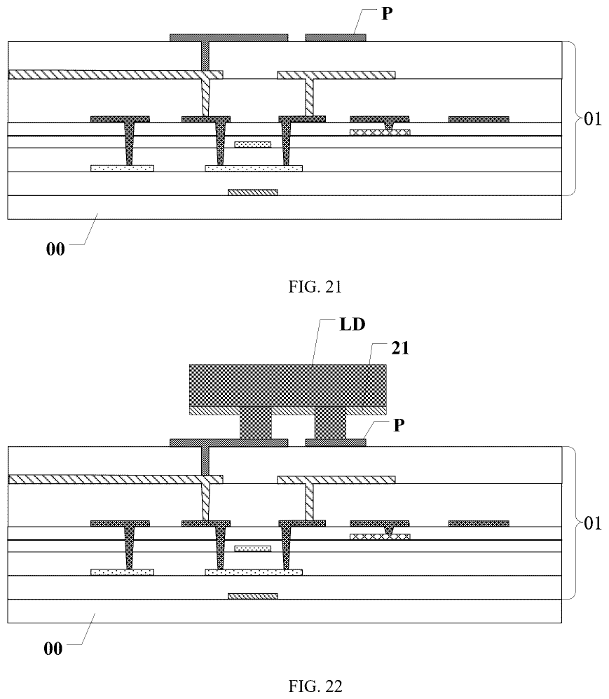

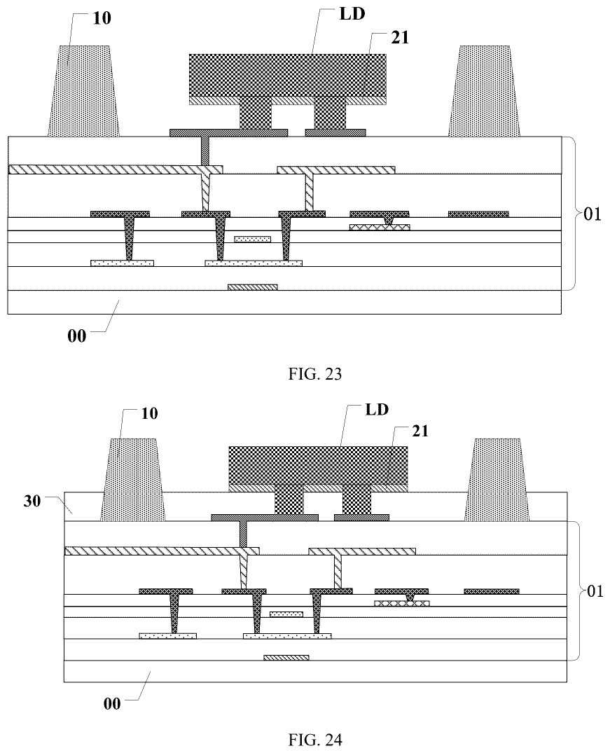

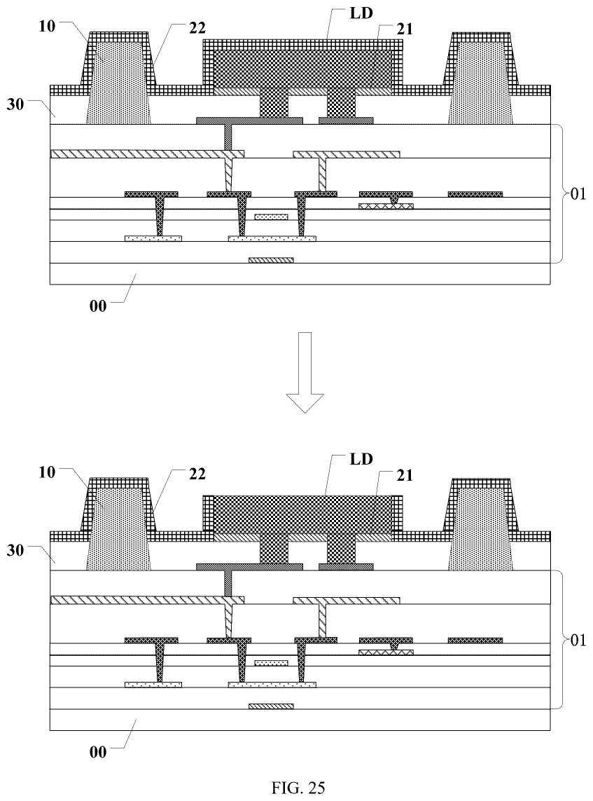

FIG. 20 is a flowchart of making a display panel, in accordance with an embodiment of the present disclosure, FIG. 21 is a schematic diagram of forming a driving layer in the process of making a display panel, FIG. 22 is a schematic diagram of binding a light emitting element LD in the process of making a display panel, FIG. 23 is a schematic diagram of forming a blocking wall 10 in the process of making a display panel, and FIG. 24 is a schematic diagram of forming a flat layer 30 in the process of making a display panel. Referring to FIGS. 20-24, the present disclosure provides a method for making a display panel, including:
Step S01: Referring to FIG. 21, provide a substrate 00, and make a driving layer on one side of the substrate 00, where a side of the driving layer facing away from the substrate 00 includes a connection pad. It should be noted that the specific process of making the driving layer on one side of the substrate 00 may refer to the relevant technology, which is not limited in the present disclosure. The specific structure of the driving layer may also refer to the structure of the existing technologies, which is not limited in the present disclosure.
Step S02: Referring to FIG. 22, bond a light emitting element LD to the side of the driving layer facing away from the substrate 00, so that the light emitting element LD is electrically connected to the connection pad P, and provide a first reflective layer 21 on the side of the epitaxial layer of the light emitting element LD facing the driving layer. Optionally, the first reflective layer 21 may be formed as a part of the light emitting element LD, or may be formed on one side of the light emitting element LD before bonding the light emitting element LD, which is not limited in the present disclosure.
Step S03: Referring to FIG. 23, form a blocking wall 10, where the blocking wall 10 is located between adjacent light emitting elements LD, and the blocking wall 10 is disposed between adjacent light emitting elements LD. The upper surface of the blocking wall 10 may be higher than the upper surface of the light emitting element LD, thereby realizing the function of blocking light and avoiding the problem of light crosstalk between light emitting elements LD of different colors.
Step S04: Referring to FIG. 24, form a flat layer 30 at least between the blocking wall 10 and the light emitting element LD. The flat layer 30 may be, for example, a black light-shielding layer. A flat surface is formed by the flat layer 30, and at the same time, the metal structure in the array layer 02 and the electrodes of the light emitting element LD are shielded to avoid the problem of metal reflection.
Step S05: Referring to FIGS. 2-4, form a second reflective layer 22, where the second reflective layer 22 is located on the sidewall of the blocking wall 10 facing the light emitting element LD, and/or the second reflective layer 22 is located on the sidewall of the light emitting element LD.

In the display panel provided by the embodiments of the present disclosure, the first reflective layer 21 may be formed as a part of the light emitting element LD or may be made on one side of the light emitting element LD before the light emitting element LD is bound. The second reflective layer 22 is formed after the preparation of the blocking wall 10 and the preparation of the flat layer 30 are completed, so as to form a structure as shown in FIG. 2, FIG. 3 or FIG. 4. When the light emitting element LD emits light, part of the light rays directed to the bottom of the light emitting element LD may be emitted from the light emitting surface of the display panel after being reflected by the first reflective layer 21, and part of the light rays with a large viewing angle may be emitted from the light emitting surface of the display panel after being reflected by the second reflective layer 22. In this way, the light rays that originally could not be emitted from the light emitting surface of the display panel are effectively utilized by the first reflective layer 21 and the second reflective layer 22, so that this part of the light rays may be emitted from the light emitting surface of the display panel, which effectively improves the light utilization rate of the light emitting element LD, thereby facilitating the improvement of the overall display brightness of the display panel.

FIG. 25 is a schematic diagram showing a process of making a display panel in which a second reflective layer 22 is formed. Referring to FIG. 25, in some embodiments, in the above Step S05, the second reflective layer 22 is formed. Specifically, the second reflective layer 22 covers the blocking wall 10, the flat layer 30 and the side of the light emitting element LD facing away from the substrate 00, and at least the second reflective layer 22 located on the surface of the light emitting element LD facing away from the substrate 00 is removed.

Continue to refer to FIG. 25, when forming the second reflective layer 22 on the display panel, the second reflective layer 22 with a whole-surface structure may be formed on the blocking wall 10, the flat layer 30 and the side of the light emitting element LD away from the substrate 00, so that the upper surface of the blocking wall 10, the sidewall of the blocking wall 10, the upper surface of the flat layer 30, the sidewall and the upper surface of the light emitting element LD are all covered by the second reflective layer 22. The second reflective layer 22 on the upper surface of the light emitting element LD is then removed by etching or other methods, and the second reflective layer 22 in other areas is retained, so that the coverage area of the second reflective layer 22 may be increased, and the reflection amount of the second reflective layer 22 to light may be increased. It should be noted that when the second reflective layer 22 includes a stacked Bragg reflective layer, the corresponding sub-reflective layer may be formed layer by layer by multiple deposition or evaporation methods, which is not limited in the present disclosure. The thickness of the second reflective layer 22 on the sidewall of the light emitting element LD may be the same as or different from the thickness of the second reflective layer 22 on the sidewall of the blocking wall 10. When the thickness of the second reflective layer 22 on the sidewall of the light emitting element LD is different from the thickness of the second reflective layer 22 in other areas, for example, when the thickness of the second reflective layer 22 on the sidewall of the light emitting element LD is less than the thickness of the second reflective layer 22 on the sidewall of the blocking wall 10, after uniformly evaporating a portion of the second reflective layer 22, the second reflective layer 22 may be continuously evaporated in other areas except the sidewall of the light emitting element LD, so that the thickness of the second reflective layer 22 on the sidewall of the blocking wall 10 is greater than the thickness of the second reflective layer 22 on the sidewall of the light emitting element LD. This avoids the problem of the second reflective layer 22 on the sidewall of the light emitting element LD being too thick and causing the second reflective layer 22 to peel off from the sidewall of the light emitting element LD.

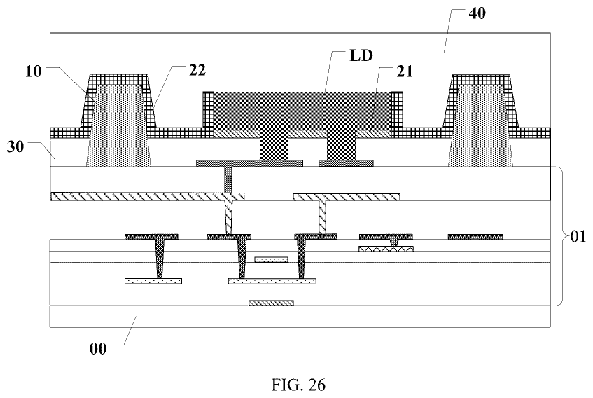

It should be noted that after the second reflective layer 22 is formed, an encapsulation layer 40 may also be formed on the side of the second reflective layer 22 facing away from the substrate 00. For example, referring to FIG. 26, which is a schematic diagram of forming an encapsulation layer in the process of making a display panel. The encapsulation layer 40 covers the side of the second reflective layer 22 facing away from the substrate 00 and covers the light emitting element LD, forming a flat surface on the side of the light emitting element LD facing away from the substrate 00 to prevent external moisture, oxygen, etc., from interfering with the light emitting element LD, which is beneficial to improving the light emitting reliability of the display panel.

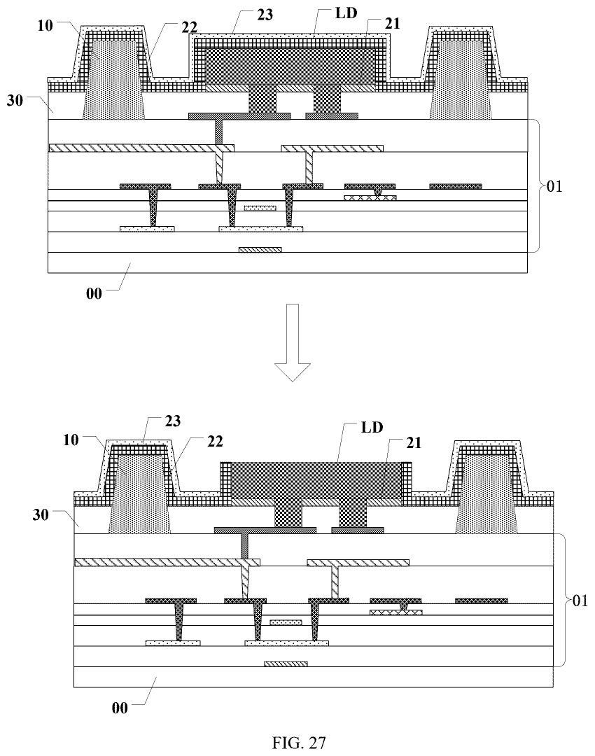

FIG. 27 is a schematic diagram of forming a second reflective layer 22 and a third reflective layer 23 in the process of making a display panel. Referring to FIG. 27, in some embodiments, before removing the second reflective layer 22 on the surface of the light emitting element LD facing away from the substrate 00, the process also includes: forming a third reflective layer 23 on the side of the second reflective layer 22 facing away from the substrate 00, and at least removing the third reflective layer 23 on the surface of the light emitting element LD facing away from the substrate 00. The reflectivity of the third reflective layer 23 is greater than the reflectivity of the second reflective layer 22.

When it is necessary to introduce the third reflective layer 23 into the display panel, after the second reflective layer 22 of the whole-surface structure is formed on the blocking wall 10, the flat layer 30, and the side of the light emitting element LD away from the substrate 00, the second reflective layer 22 on the surface of the light emitting element LD is not removed first, but the third reflective layer 23 is first formed on the side of the second reflective layer 22 of the whole-surface structure away from the substrate 00, for example, by evaporating a whole-surface metal reflective layer. The third reflective layer 23 and the second reflective layer 22 are then removed at some area(s) by etching and other processes. The third reflective layer 23 is a metal reflective layer, which has a higher reflectivity than, for example, a Bragg reflective layer. Introducing the third reflective layer 23 into the display panel is conducive to further improving the light utilization rate of the display panel. Moreover, the method of forming the third reflective layer 23 on the surface of the second reflective layer 22 avoids the problem of being unable to be effectively fixed when the third reflective layer 23 is directly formed on the blocking wall 10 and other structures.

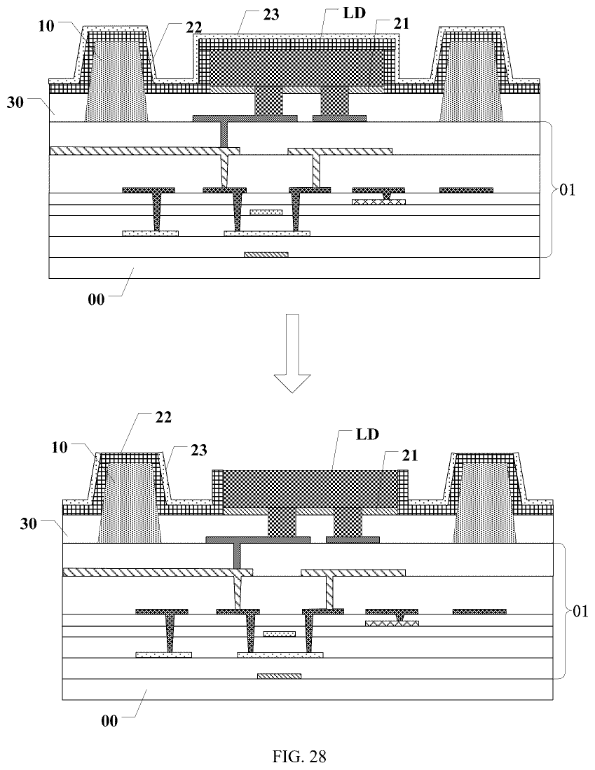

Referring to FIG. 28, which is another schematic diagram of forming the second reflective layer 22 and the third reflective layer 23 in the process of making a display panel. In some embodiments, after the third reflective layer 23 is formed on the side of the second reflective layer 22 away from the substrate 00, the third reflective layer 23 on the surface of the blocking wall 10 away from the substrate 00 is removed. When the third reflective layer is a metal reflective layer with a high reflectivity, if a large area of the metal reflective layer is formed on the display panel, there will be a high probability of short circuit risk. For this reason, in addition to removing the third reflective layer 23 on the surface of the light emitting element LD away from the substrate 00, the third reflective layer 23 on the surface of the blocking wall 10 away from the substrate 00 may also be removed, thereby avoiding the appearance of a large area of the third reflective layer 23 and avoiding the occurrence of short circuit problems. Retaining the third reflective layer 23 at least on the sidewall of the blocking wall 10 may increase the reflectivity of the light of a large viewing angle emitted by the light emitting element LD, thereby improving the effective utilization rate of the light emitted by the light emitting element LD. For other scattered light, it may be reflected by the second reflective layer 22 in other areas, which is also conducive to improving the overall display brightness of the display panel.

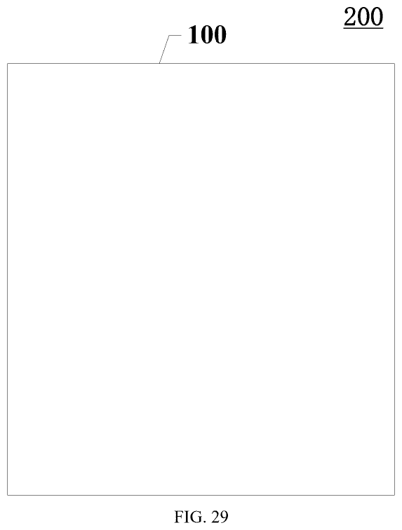

Based on the same inventive concept, the present disclosure also provides a display device. FIG. 29 is a schematic structural diagram of a display device 200, in accordance with an embodiment of the present disclosure. Referring to FIG. 29, the display device 200 includes a display panel in any of the above embodiments. The display device 200 provided in the embodiments of the present disclosure may be any electronic device with a display function, such as a touch screen, a mobile phone, a tablet computer, a laptop computer, an e-book, or a television. The display device 200 provided in the embodiments of the present disclosure has the beneficial effects of the display panel provided in the embodiments of the present disclosure. For details, refer to the specific description of the display panel in the above embodiments, which will not be repeated here.

It should be noted that FIG. 29 only illustrates one shape of the display device 200 by taking a rectangular structure as an example. In some embodiments, the display device 200 may also be circular, elliptical or any other feasible shape, which is not limited in the present disclosure.

Compared with the existing technologies, the technical solutions provided by the embodiments of the present disclosure have the following advantages.

In the display panel and its manufacturing method and display device provided by the embodiments of the present disclosure, a first reflective layer is introduced on the side of the epitaxial layer of the light emitting element facing the substrate, and a second reflective layer is introduced on the sidewall of the light emitting element facing the blocking wall, and/or on the sidewall of the light emitting element. When the light emitting element emits light, part of the light rays emitted toward the bottom of the light emitting element may be emitted from the light emitting surface of the display panel after being reflected by the first reflective layer. Part of the light rays with a large viewing angle may be emitted from the light emitting surface of the display panel after being reflected by the second reflective layer. In this way, through the reflection of the first reflective layer and the second reflective layer, the light rays that could not originally be emitted from the light emitting surface of the display panel are effectively utilized, so that this part of the light rays may be emitted from the light emitting surface of the display panel, which effectively improves the light utilization rate of the light emitting element. This is equivalent to improving the light emitting brightness of the corresponding light emitting element, thereby facilitating improving the overall display brightness of the display panel.

It should be noted that, in this disclosure, relational terms such as “first” and “second” are only used to distinguish one entity or operation from another entity or operation, and do not necessarily require or imply any such actual relationship or order between these entities or operations. Moreover, the terms “include”, “comprise” or any other variants thereof are intended to cover non-exclusive inclusion, so that a process, method, article or device including a series of elements includes not only those elements, but also other elements not explicitly listed, or also includes elements inherent to such process, method, article or device. In the absence of further restrictions, the elements defined by the sentence “comprise a . . . ” do not exclude the existence of other identical elements in the process, method, article or device including the elements.

The above descriptions are merely some specific embodiments of the present disclosure, so that those skilled in the art may understand or implement the present disclosure. Various modifications to these embodiments will be apparent to those skilled in the art, and the general principles defined herein may be implemented in other embodiments without departing from the spirit or scope of the present disclosure. Therefore, the present disclosure will not be limited to the embodiments described herein, but will conform to the widest scope consistent with the principles and novel features disclosed herein.

What is claimed is:

1. A display panel, comprising:
a substrate;
a driving layer disposed on one side of the substrate;
a light emitting element and a blocking wall disposed on a side of the driving layer away from the substrate, wherein the blocking wall is at least located between adjacent light emitting elements in a direction parallel to a plane where the substrate is located; and
a first reflective layer and a second reflective layer, wherein the first reflective layer is located on a side of an epitaxial layer of the light emitting element facing the driving layer, and the second reflective layer is located on a sidewall of the blocking wall facing the light emitting element, and/or the second reflective layer is located on a sidewall of the light emitting element.

2. The display panel according to claim 1, wherein the second reflective layer is located on the sidewall of the blocking wall facing the light emitting element.

3. The display panel according to claim 2, wherein a thickness of the first reflective layer is smaller than a thickness of the second reflective layer.

4. The display panel according to claim 3, wherein the first reflective layer includes M groups of first Bragg reflective layers, and the second reflective layer includes N groups of second Bragg reflective layers, wherein 1≤M□N, and M and N are both integers; or
the first reflective layer includes M groups of first Bragg reflective layers, and the second reflective layer includes N groups of second Bragg reflective layers, wherein 1≤M=N, and M and N are both integers, and a thickness of a first Bragg reflective layer is less than a thickness of a second Bragg reflective layer.

5. The display panel according to claim 3, wherein the thickness of the first reflective layer is H1, wherein 1 um≤H1≤1.5 um, and the thickness of the second reflective layer is H2, wherein 2 um≤H2.

6. The display panel according to claim 2, wherein:
the first reflective layer includes M groups of first Bragg reflective layers, the second reflective layer includes N groups of second Bragg reflective layers, wherein M≥1, N≥1, and M and N are both integers;
at least one of the first Bragg reflection layers includes a first sub-reflection layer and a second sub-reflection layer, wherein the first sub-reflection layer and the second sub-reflection layer have different refractive indices, and/or the first sub-reflection layer and the second sub-reflection layer have different thicknesses; and
at least one of the second Bragg reflection layers includes a third sub-reflection layer and a fourth sub-reflection layer, wherein the third sub-reflection layer and the fourth sub-reflection layer have different refractive indices, and/or the third sub-reflection layer and the fourth sub-reflection layer have different thicknesses.

7. The display panel according to claim 1, wherein a distance between a surface of the blocking wall facing away from the substrate and the substrate is h1, and a distance between a surface of the light emitting element facing away from the substrate and the substrate is h2, wherein h1≥h2.

8. The display panel according to claim 1, further comprising a flat layer, wherein:
the flat layer is located at least between the blocking wall and the light emitting element along a direction parallel to the substrate; and
the flat layer is located on a side of the first reflective layer facing the substrate along a direction perpendicular to the substrate.

9. The display panel according to claim 8, wherein:
a spacing area is provided between the light emitting element and a blocking wall adjacent to the light emitting element, the second reflective layer is also located in the spacing area and on a side of the flat layer away from the substrate; and
the second reflective layer located in the spacing area is connected to the second reflective layer located on the sidewall of the light emitting element, and/or the second reflective layer located in the spacing area is connected to the second reflective layer located on the sidewall of the blocking wall.

10. The display panel according to claim 9, wherein the first reflective layer contacts the second reflective layer located in the spacing area;
the first reflective layer includes a first portion, a second portion and a connecting portion connecting the first portion and the second portion, wherein the first portion and the second portion are respectively parallel to the plane where the substrate is located; and
along a direction perpendicular to the plane where the substrate is located, the connecting portion is located between the first portion and the second portion, the second portion is located on a side of the connecting portion away from the substrate, and the second portion contacts the second reflective layer, located in the spacing area, on a side facing the spacing area.

11. The display panel according to claim 10, wherein:
a surface of the second portion facing the substrate is flush with a surface of the second reflective layer in the spacing area facing the substrate; or
along a direction from the spacing area to the light emitting element, at least part of a sub-reflection layer in the second portion overlaps with the flat layer in the spacing area, and at least part of a sub-reflection layer in the second portion does not overlap with the flat layer in the spacing area, wherein the sub-reflection layer in the second portion that does not overlap with the flat layer contacts the second reflective layer in the spacing area; or
along a direction perpendicular to the substrate, the second portion is located between two surfaces of the second reflective layer, in the spacing area, that are parallel to the substrate.

12. The display panel according to claim 9, wherein:
along a direction of the blocking wall pointing to the light emitting element, the first reflective layer and the second reflective layer located in the spacing area are isolated by the flat layer; and/or,
along a direction perpendicular to the plane where the substrate is located, the first reflective layer and the second reflective layer located in the spacing area are isolated by the flat layer.

13. The display panel according to claim 8, wherein a spacing area is provided between the light emitting element and the blocking wall adjacent to the light emitting element, and a width of the spacing area along a direction of the blocking wall pointing toward the light emitting element is smaller than a width of the light emitting element.

14. The display panel according to claim 13, wherein the display panel includes at least two light emitting elements of different light emitting colors, and widths of spacing areas corresponding to the light emitting elements of different light emitting colors are different.

15. The display panel according to claim 1, wherein:
the second reflective layer includes a first section located on the sidewall of the light emitting element and a second section located on the sidewall of the blocking wall; and
a thickness of the first section is S1, a thickness of the second section is S2, and a thickness of the first reflective layer is S3, wherein S1□S3□S2.

16. The display panel according to claim 1, wherein:
the light emitting element includes a first color light emitting element and a second color light emitting element;
a light emitting efficiency of the first color light emitting element is lower than a light emitting efficiency of the second color light emitting element;
a thickness of a first reflective layer corresponding to the first color light emitting element is greater than a thickness of a first reflective layer corresponding to the second color light emitting element;
the first reflective layer corresponding to the first color light emitting element includes M1 groups of first Bragg reflective layers, and the first reflective layer corresponding to the second color light emitting element includes M2 groups of first Bragg reflective layers, wherein M1>M2, or M1=M2; and
a thickness of a first Bragg reflective layer corresponding to the first color light emitting element is greater than a thickness of a first Bragg reflective layer corresponding to the second color light emitting element.

17. A method for making a display panel, comprising:
providing a substrate, and forming a driving layer on one side of the substrate, wherein a side of the driving layer facing away from the substrate includes a connection pad;
binding a light emitting element to the side of the driving layer facing away from the substrate, so that the light emitting element is electrically connected to the connection pad, and providing a first reflective layer on a side of an epitaxial layer of the light emitting element facing the driving layer;
forming a blocking wall, wherein the blocking wall is located between adjacent light emitting elements;
forming a flat layer at least between the blocking wall and the light emitting element; and
forming a second reflective layer so that the second reflective layer is located on a sidewall of the blocking wall facing the light emitting element, and/or the second reflective layer is located on a sidewall of the light emitting element.

18. The method according to claim 17, wherein forming the second reflective layer further comprises:
covering the blocking wall, the flat layer and a side of the light emitting element facing away from the substrate with the second reflective layer; and
removing the second reflective layer at least located on a surface of the light emitting element facing away from the substrate.

19. The method according to claim 18, wherein, before removing the second reflective layer on the surface of the light emitting element facing away from the substrate, the method further comprises:
forming a third reflective layer on a side of the second reflective layer facing away from the substrate; and
removing the third reflective layer at least on the surface of the light emitting element facing away from the substrate, wherein a reflectivity of the third reflective layer is greater than a reflectivity of the second reflective layer.

20. A display device, comprising a display panel, wherein the display panel includes:
a substrate;
a driving layer disposed on one side of the substrate;
a light emitting element and a blocking wall disposed on a side of the driving layer away from the substrate, wherein the blocking wall is at least located between adjacent light emitting elements in a direction parallel to a plane where the substrate is located; and
a first reflective layer and a second reflective layer, wherein the first reflective layer is located on a side of an epitaxial layer of the light emitting element facing the driving layer, and the second reflective layer is located on a sidewall of the blocking wall facing the light emitting element, and/or the second reflective layer is located on a sidewall of the light emitting element.
